(19) United States
(12) Patent Application Publication
(10) Pub. No.: US 2026/0305423 A1
(43) Pub. Date: Oct. 1, 2026

(54) PATCH PACKAGING ARCHITECTURE IMPLEMENTING HYBRID BONDS AND SELF-ALIGNED TEMPLATE

(71) Applicant: Intel Foundry IP LLC, Santa Clara, CA (US)

(72) Inventors: Jeremy Ecton, Gilbert, AZ (US); Gang Duan, Chandler, AZ (US); Srinivas V. Pietambaram, Chandler, AZ (US); Brandon C. Marin, Gilbert, AZ (US); Bai Nie, Chandler, AZ (US)

(73) Assignee: Intel Foundry IP LLC, Santa Clara, CA (US)

(21) Appl. No.: 19/698,984

(22) Filed: Jun. 5, 2026

Related U.S. Application Data
(63) Continuation of application No. 17/473,414, filed on Sep. 13, 2021.

(51) Int. Cl. H10W 70/685; H10W 70/05; H10W 70/69; H10W 70/692; H10W 74/10; H10W 80/00; H10W 90/00

(52) U.S. Cl. CPC H10W 70/685; H10W 70/05; H10W 70/095; H10W 70/69; H10W 70/692; H10W 74/114; H10W 80/00; H10W 90/00; H10W 90/794

(57) ABSTRACT

A substrate of a microelectronic assembly is provided, the substrate comprising conductive traces through an organic dielectric, and a coating comprising silicon and oxygen. The substrate is configured to couple with a component electrically and mechanically by at least one or more conductive via through the coating, the conductive via being electrically connected to the conductive traces, such that the coating is between the organic dielectric and the component when coupled. In some embodiments, the component includes another coating comprising silicon and oxygen, with conductive vias through the second coating. The conductive vias and the coating of the substrate are configured to bind with the conductive vias and the coating of the component respectively to form hybrid bonds.

### CROSS-REFERENCE TO RELATED APPLICATION

This application is a continuation of (and claims the benefit and priority under 35 U.S.C. 120 of) U.S. patent application Ser. No. 17/473,414, filed Sep. 13, 2021, entitled “PATCH PACKAGING ARCHITECTURE IMPLEMENTING HYBRID BONDS AND SELF-ALIGNED TEMPLATE,” the disclosure of which is considered part of, and is incorporated by reference in, the disclosure of this application.

### TECHNICAL FIELD

The present disclosure relates to techniques, methods, and apparatus directed to patch packaging architecture implementing hybrid bonds and self-aligned template.

### BACKGROUND

Electronic circuits when fabricated on a wafer of semiconductor material, such as silicon, are commonly called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system. Some ICs have specific functionalities, such as memory or processing. Some other ICs have multiple functionalities, such as a system-on-chip (SOC), in which all or most components of a computer or other electronic system are integrated into a single monolithic die.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a simplified cross-sectional view of an example patch packaging architecture, according to some embodiments of the present disclosure.

FIG. 1B is a simplified cross-sectional view of structural details of the packaging architecture of FIG. 1A.

FIG. 2A is a simplified cross-sectional view of another example patch packaging architecture, according to some embodiments of the present disclosure.

FIG. 2B is a simplified cross-sectional view of structural details of the packaging architecture of FIG. 2A.

FIG. 3A is a simplified cross-sectional view of yet another example patch packaging architecture, according to some embodiments of the present disclosure.

FIG. 3B is a simplified cross-sectional view of structural details of the packaging architecture of FIG. 3A.

FIG. 4A is a simplified cross-sectional view of yet another example patch packaging architecture, according to some embodiments of the present disclosure.

FIG. 4B is a simplified cross-sectional view of structural details of the packaging architecture of FIG. 4A.

FIG. 5 is a simplified cross-sectional view of yet another example patch packaging architecture, according to some embodiments of the present disclosure.

FIG. 6 is a simplified cross-sectional view of yet another example patch packaging architecture, according to some embodiments of the present disclosure.

FIG. 7A is a simplified cross-sectional view of yet another example patch packaging architecture, according to some embodiments of the present disclosure.

FIGS. 7B-7D are simplified cross-sectional views of structural details according to various embodiments of the packaging architecture of FIG. 7A.

FIGS. 8A-8H are simplified cross-sectional views illustrating various manufacturing steps associated with an example patch packaging architecture, according to some embodiments of the present disclosure.

FIGS. 9A-9F are simplified cross-sectional views illustrating various manufacturing steps associated with an example patch packaging architecture, according to some embodiments of the present disclosure.

FIGS. 10A-10D are simplified cross-sectional views illustrating processing details associated with various manufacturing processes of an example patch packaging architecture, according to some embodiments of the present disclosure.

FIGS. 11A-11E are simplified cross-sectional views illustrating various manufacturing steps associated with an example patch packaging architecture, according to some embodiments of the present disclosure.

FIGS. 12A-12F are simplified cross-sectional views illustrating various manufacturing steps associated with an example patch packaging architecture, according to some embodiments of the present disclosure.

FIGS. 13A-13E are simplified cross-sectional views illustrating various manufacturing steps associated with an example patch packaging architecture, according to some embodiments of the present disclosure.

FIG. 14 is a cross-sectional view of a device package that may include one or more microelectronic assemblies in accordance with any of the embodiments disclosed herein.

FIG. 15 is a cross-sectional side view of a device assembly that may include one or more microelectronic assemblies in accordance with any of the embodiments disclosed herein.

FIG. 16 is a block diagram of an example computing device that may include one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in a way that limits the broad scope of the present disclosure and its potential applications.

The demand for miniaturization of form factor and increased levels of integration for high performance in ICs are driving sophisticated packaging approaches in the semiconductor industry. Die partitioning enables miniaturization of small form factor and high performance without yield issues seen with other methods but needs fine die-to-die interconnections. Embedded bridge dies (e.g., Embedded Multi-die Interconnect Bridge (EMIB)) can enable lower cost and simpler 2.5D packages for very high-density interconnects between heterogeneous dies on a single package. Instead of an expensive silicon interposer with one or more through-silicon via (TSV), a relatively small silicon bridge die is embedded in the package, enabling lateral electrical coupling between adjacent ICs, enabling very high-density silicon-level die-to-die connections only where needed. Standard flip-chip assembly is used for robust power delivery and to connect high-speed signals directly from chip to the package substrate.

Currently available bridge die packaging technology suffers from high cumulative Bump Thickness Variation (BTV) across one or more dies. With finer bump pitches and smaller interconnect sizes, high BTV can lead to manufacturing yield loss as also performance degradation during operation, especially in cases where numerous such embedded bridge dies are used. Thus, there is a need for several such bridge dies that can provide lateral electrical connections to adjacent IC dies at fine bump pitches of 25 microns or lower.

Current approaches for enabling such a packaging architecture uses vias through an intermediary substrate, called an interposer, typically made of organic materials, such as epoxy used in mold compounds, with through-mold vias (TMVs), embedded bridge dies optionally having TSVs, and redistribution layers (RDLs) on at least one side of the interposer that couples to the IC dies. The RDLs are required because the interposers, being made of organic materials, are not capable of enabling as fine a via pitch of the TMVs as semiconductor die bond pads. In such a packaging architecture, the dies are assembled on the RDL first, and then another RDL is patterned on another side of the interposer opposite to the IC dies because of the pitch differential between interconnects in the interposer and interconnects in the package substrate. This RDL patterning process is risky (e.g., low yield), because of the propensity to lose expensive known good dies (KGDs) in the process. It is desired therefore, to have an alternate packaging architecture that can enable a die-last assembly process, in which the RDLs on either side of the interposer are patterned before attaching the IC dies thereto.

Another challenge in such packaging architecture is the inability to achieve very fine interconnect pitches with the organic materials-based interposer or substrate. Hybrid copper-to-copper and silicon oxide-silicon-oxide bonding provides the finest pitch in current IC die technologies; such interconnects are feasible between two stacked IC dies, for example. However, such hybrid bonding between IC dies and organic interposers of package substrates is not possible currently because of the lack of planarity in the substrates due to the nature of the organic materials and their processing. Without highly planar substrates, the hybrid bonds may not be formed properly, resulting in manufacturing yield loss. Thus, there is a need for improving the planarity of surfaces being coupled so that hybrid bonds are achievable with relatively lower yield losses.

In one aspect of the present disclosure, an example package architecture includes a substrate of a microelectronic assembly, the substrate comprising: conductive traces through an organic dielectric with a coating comprising silicon and oxygen. The substrate is configured to couple with a component electrically and mechanically by at least one or more conductive via through the coating, the conductive via being electrically connected to the conductive traces, such that the coating is between the dielectric and the component when coupled. In some embodiments, the coupling is by way of one or more “hybrid bond,” which, as used herein, refers to a combination of (a) a bond between dielectric materials such as oxides of silicon, and (b) a metal bond (e.g., between two copper pads) to form permanent interconnections. It is also known as “direct bond interconnect,” (DBI). Note that the term “bond” as used herein refers to a permanent chemical attachment (e.g., ionic or covalent bond) rather than a mere mechanical attachment, for example, between dissimilar materials, such as an IC die and die attach adhesive. According to various embodiments as described herein, such hybrid bonds are formed at an interface between two organic substrates or between an IC die and an organic substrate with the use of a glass or silicon oxide coating on the substrate proximate to the bonding interface. In one embodiment, the substrate comprises an organic core; in another embodiment, the substrate comprises a glass core for higher planarity. Additionally, some embodiments permit die-last processing, enabling higher yields than achievable with current processes as described above.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are stated in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of input/output (I/O) functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified.

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., metal oxide semiconductor (MOS) FETs (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

The term “interconnect” may be used to describe any element formed of an electrically conductive material for providing electrical connectivity to one or more elements associated with an IC or/and between various such elements. As used herein, the term “interconnect” may refer to both conductive traces (also sometimes referred to as “lines,” “wires,” “metal lines” or “trenches”) and conductive vias (also sometimes referred to as “vias” or “metal vias”). Sometimes, traces and vias may be referred to as “conductive traces” and “conductive vias”, respectively, to highlight the fact that these elements include electrically conductive materials such as metals.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “metallization stack” may be used to refer to a stack of one or more interconnects for providing connectivity to different circuit components of an IC die/chip and/or a package substrate.

In context of a stack of dies coupled to one another or in context of a die coupled to a package substate, the term “interconnect” may also refer, respectively, to die-to-die (DTD) interconnects and die-to-package substrate (DTPS) interconnects.

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be unpackaged dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 7 microns and 100 microns. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc. ; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photo-imageable polymers. In some embodiments, solder resist may be non-photo-imageable.

The terms “substantially,” “close,” “approximately,” “near,” and “about,” generally refer to being within +/−20% of a target value (e.g., within +/−5 or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

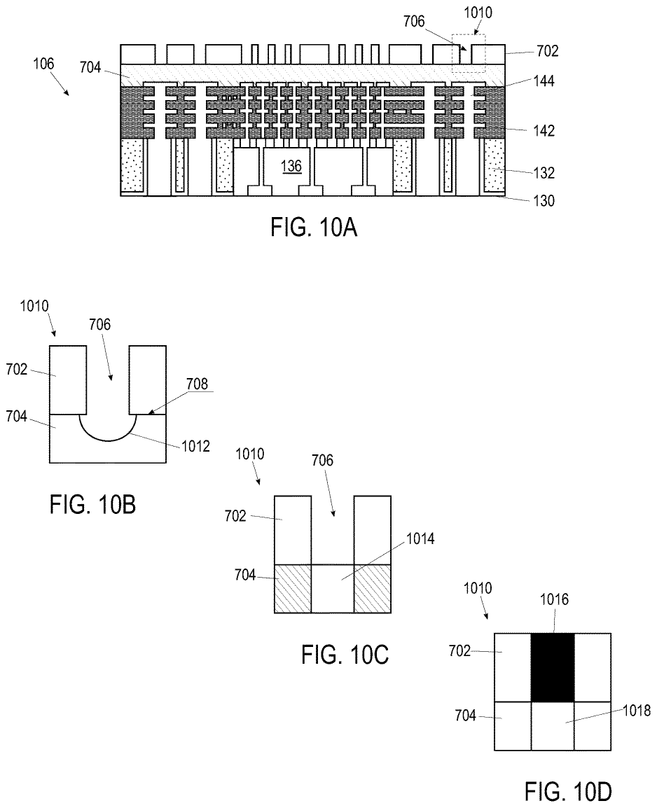

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 110a-110e), such a collection may be referred to herein without the letters (e.g., as “110”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

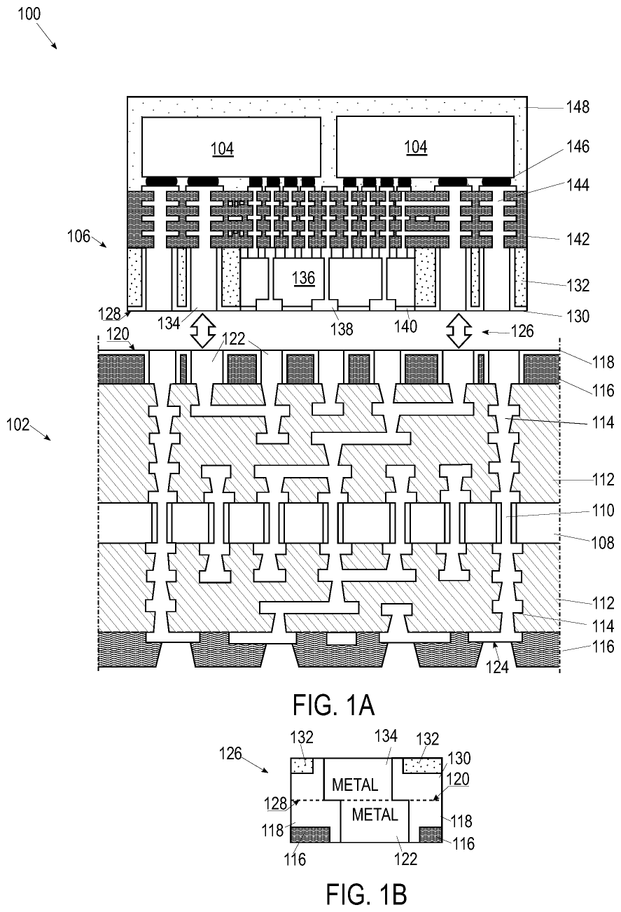

FIG. 1A is a schematic cross-sectional illustration of a portion of a microelectronic assembly 100, according to some embodiments of the present disclosure. An example embodiment comprises a first substrate 102 to which is coupled one or more IC die 104 with a second substrate 106. Substrate 102 and substrate 106 may be interchangeable in some embodiments, and alternatively may be of different types in other embodiments. In a general sense, any process described herein with reference to substrate 102 may be adapted suitably to apply to substrate 106 as well due to the structural and material similarities between the two unless otherwise particularly noted.

According to currently accepted terminology among those with ordinary skill in the art, three different types of substrates are described herein: (1) “package substrate;” (2) “interposer;” and (3) “patch substrate.” A “package substrate,” as used herein refers to a structure that provides mechanical support and electrical coupling for one or more IC dies to components of a larger electronic system through a printed circuit board (PCB) (also known as a motherboard). An “interposer” as used herein refers to a structure that is sandwiched between two or more IC dies and the package substrate. It typically comprises lateral interconnects between the two or more IC dies and through-dielectric vias (TDVs) (also known as TMVs) that provide electrical coupling for the IC dies to the package substrate. Some interposers also house other IC dies within its structure, for example, embedded in cavities therein. The interposer typically has the same or similar footprint as the package substrate. A “patch substrate,” as used herein, refers to a dimensionally smaller sized package substrate. The patch substrate is similar to the interposer in relative location, cross-section, and functionality sandwiched between the package substrate and IC dies, but it has a smaller footprint. Several sub-assemblies of KGDs on patch substrates may be coupled together on a single package substrate as shown for example, in FIG. 1A. These multi-chip modules on the patch substrate may operate together as a sub-component in the larger package, functioning as memory modules or processing modules, for instance. In other words, a patch substrate is to a package substrate what the latter is to a motherboard in a typical electronic system. In some embodiments, substrate 102 comprises a package substrate, and substrate 106 comprises an interposer. In other embodiments, substrate 102 comprises a package substrate and substrate 106 comprises a patch substrate. In yet other embodiments, substrate 102 and substrate 106 are interchangeable and may comprise any two of package substrate, interposer and patch substrate.

In the example embodiment shown, substrate 102 comprises a core 108 with through-vias 110, which may also function as inductors in certain embodiments. In some embodiments, core 108 comprises glass fiber-reinforced epoxy core, such as Fire-Retardant-4 (FR4). In other embodiments, core 108 comprises bulk transparent glass, ceramic, or other such stiff, insulating, inorganic material, including any type of bulk amorphous or polycrystalline transparent, opaque, or semi-transparent glass, such as fused silica, borosilicate glass, soda-lime glass, ceramic glass, etc. The presence of glass instead of an organic core, such as fiberglass-reinforced epoxy or prepreg, allows finer line widths and line spacings in substrate 102 because of the high planarity (e.g., low total thickness variation (TTV)) of the glass panel comprising core 104. In various embodiments, a TTV of side 120 of substrate 102 may be less than 10 micrometer.

A dielectric 112 may encapsulate core 108 on either side. In various embodiments, dielectric 112 may comprise Ajinomoto Buildup Film (ABF), benzocyclobutene (BCB), cyclotene, polyimide, epoxy/phenol, acrylic, and/or polybenzoxazole (PBO). In other embodiments, dielectric 112 may comprise bismaleimide-triazine (BT) resin, organic dielectrics with inorganic fillers or low-k and ultralow-k dielectric (e.g., carbon-doped dielectrics, fluorine-doped dielectrics, porous dielectrics, and organic polymeric dielectrics). Conductive traces 114, including vias, planes, and pads, may be provided on either side of core 108 through dielectric 112 using any suitable conductive material, such as copper. In various embodiments, dielectric 112 and conductive traces 114 may be formed as a plurality of alternating layers with conductive vias through dielectric 112 providing electrical coupling between two or more metal layers. In some embodiments, conductive traces 114 may comprise up to 12 layers on either side of core 108, with 2 layers on core 108 itself for a “11-2-11” type of buildup structure. A solder resist 116 may be located as an outermost insulating layer on either side of substrate 102. In some embodiments, solder resist 116 may comprise the same material as dielectric 112; in other embodiments, solder resist 116 may comprise a different material (e.g., as shown in the example embodiment of the figure).

A coating 118 comprising silicon oxide may encapsulate solder resist 116 on a side 120 proximate to substrate 106, with one or more of conductive via 122 patterned suitably to expose conductive contacts. Conductive via 122 is electrically connected to conductive traces 114. In some embodiments, based on the process used to deposit coating 118, sidewalls of conductive via 122 may be coated with the material as well. Conductive pads exposed by solder resist 116 on substrate 102 on another side opposite to substrate 106 may enable coupling to external components as appropriate, for example, to a motherboard or other such PCB by second-level interconnects (SLI) 124. Note that only the conductive contacts of SLI 124 are shown in the figure; other structural details are not shown so as not to clutter the drawing.

In various embodiments, coating 118 may provide a stiff (e.g., rigid), planar surface on side 120 with sufficiently low TTV to facilitate hybrid bonds at mid-level interconnects (MLI) 126 between side 120 of substrate 102 and a corresponding side 128 of substrate 106. In embodiments in which flatness (e.g., TTV) of side 120 is of concern, core 108 may comprise bulk glass rather than FR-4, as bulk glass can enable low warpage and shrinkage of substrate 102.

Substrate 106 includes a coating 130 comprised of silicon oxide encapsulating a dielectric material, such as mold compound 132, for example, comprising a suitable epoxy resin. Coating 130 may facilitate a lower TTV for side 128 than is possible with mold compound 132 alone. One or more of conductive via 134 in coating 130 may expose conductive contacts in substrate 102 to enable electrical coupling with corresponding conductive contacts exposed by conductive via 122 in substrate 102. In some embodiments, based on the process used to deposit coating 130, sidewalls of conductive via 134 may be coated with the material as well.

A detailed view of MLI 126 is shown in FIG. 1B. Conductive contacts on surfaces of side 120 and side 128 of substrate 102 and substrate 106 respectively (e.g., conductive contacts exposed through vias 122 and 134) bond with each other; likewise, silicon oxide in coating 118 and coating 130 of substrate 102 and substrate 106 respectively bond with each other. The bonded interconnects form MLI 126, comprising hybrid bonds, providing electrical and mechanical coupling between substrate 102 and substrate 106. Note that although MLI 126 may comprise hybrid bonds as described herein, MLI 126 may also comprise other similar die-to-die interconnections as described further below within the broad scope of the embodiments of the present disclosure.

Hybrid bonds are generally known in the art as a form of interconnection between IC dies; they are not known to be used to connect organic substrates together as described herein. The reason for their lack of use in such applications is the inability, using current techniques and processes, to create planar surfaces on organic materials with sufficiently low TTV to enable metal-to-metal contact and simultaneous oxide-to-oxide contact such that a bond is created with no interstitial holes and other irregularities that could lead to electrical shorts, electrical opens and/or other performance degradations. However, in embodiments of the present disclosure, this disadvantage is mitigated by the use of coating 118 and coating 130 over underlying organic materials, namely solder resist 116 and mold compound 132, respectively. Coating 118 and coating 130 enable planar, flat surfaces on side 120 and side 128 of substrate 102 and substrate 106 respectively such that hybrid bonding processes can be used to form MLI 126 comprising hybrid bonds.

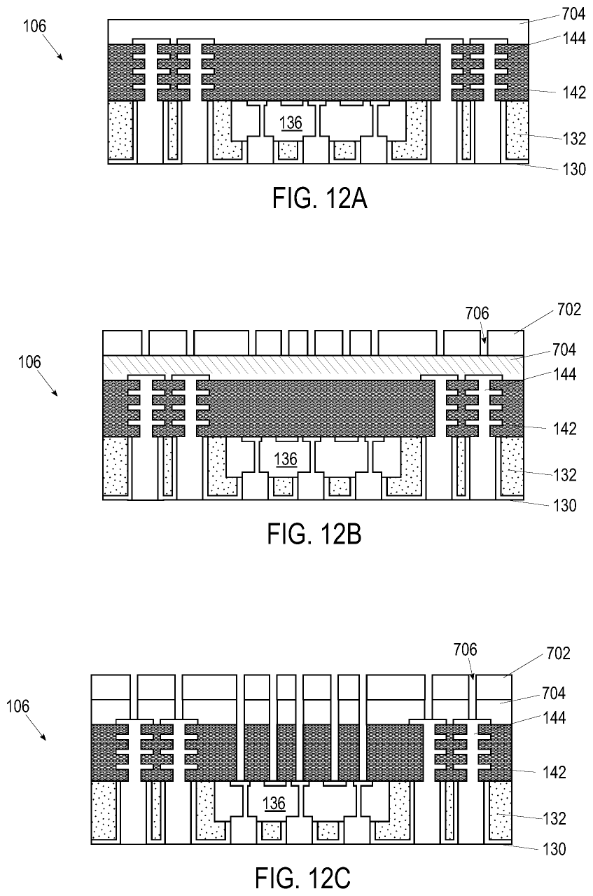

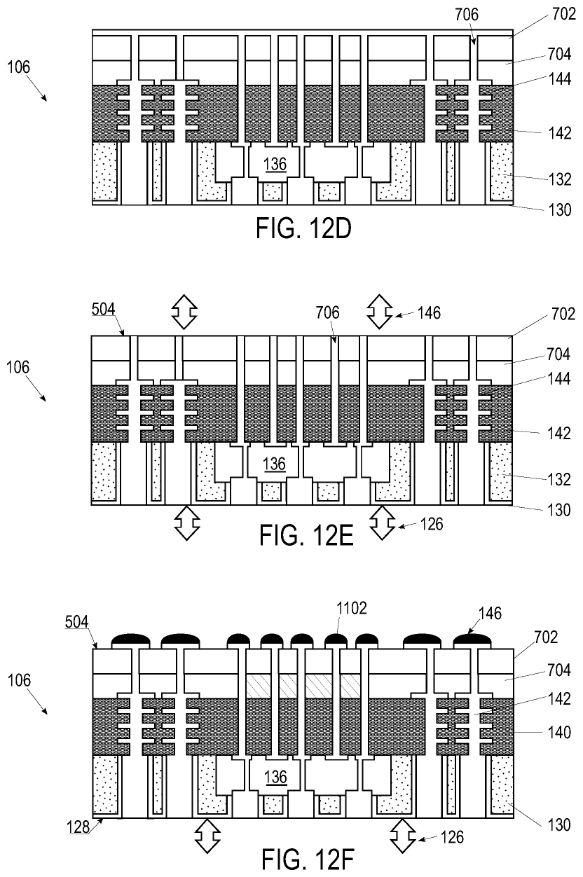

Returning to FIG. 1A, an IC die 136 may be embedded inside mold compound 132 (e.g., attached within a cavity) with a suitable adhesive, for example, comprising an industry-standard die attach material, such as liquid epoxy or polyimide film. In some embodiments, for example, as shown, IC die 136 is flush with side 128 of substrate 106; in other embodiments (not shown), embedded IC die 136 may be located within a cavity spaced apart from side 128 by mold compound 132, with TMVs providing electrical coupling appropriately (e.g., see FIG. 12E). In some embodiments where IC die 136 is flush with side 128 and has TSVs, IC die 136 may comprise one or more conductive contact 138 and a coating 140 comprised of silicon oxide. Conductive contact 138 may bond with the conductive contact exposed by conductive via 122; likewise coating 140 may bond with coating 118 of substrate 102, forming further MLI 126 comprising hybrid bonds between IC die 136 and substrate 102.

In various embodiments, substrate 106 may further comprise dielectric 142 and conductive traces 144 that together constitute an appropriate RDL. In various embodiments, the RDL may comprise one layer each of dielectric 142 and conductive traces 144; in other embodiments, the RDL may comprise multiple alternating layers of dielectric 142 and conductive traces 144 with conductive vias between two or more metal layers. Conductive via 134 is electrically coupled to conductive traces 144.

The one or more IC die 104 may be coupled to substrate 106 with first-level interconnects (FLI) 146. In various embodiments, a size of substrate 106 (e.g., thickness and footprint) may vary according to a number of interconnections required laterally between any two of IC die 104 as also with a number of IC die 104 coupled to substrate 106. For example, larger number of interconnections between two of IC die 104 may lead to greater number of dielectric layers and metal layers constituting dielectric 142 and conductive traces 144 in substrate 106. In another example, larger number of IC die 104 coupled laterally on substrate 106 may require a larger footprint of substrate 106 to accommodate all of them.

The one or more of IC die 104 may be encapsulated in another mold compound 148. In some embodiments, the material comprised in mold compound 148 may be the same as that comprised in mold compound 132; in other embodiments, the material comprised in mold compound 148 may be different from that comprised in mold compound 132. In some embodiments (not shown) other components, such as heat sinks may be coupled to microelectronic assembly 100 based on particular needs.

In some embodiments, IC die 136 may comprise only passive elements, for example, conductive traces and vias with resistors and capacitors fabricated in metallization layers with inter-layer dielectric (ILD) over a silicon substrate; in other embodiments, IC die 136 may comprise active elements also, including transistors, diodes, and the like. The choice of using active elements in IC die 136 may vary depending on desired functionalities, performance, cost, and manufacturing considerations of microelectronic assembly 100. In some embodiments, IC die 136 may comprise TSVs; in other embodiments, IC die 136 may not comprise TSVs. IC die 136 may be any suitable IC fabricated on a semiconductor substrate within the broad scope of the present disclosure.

In various embodiments, IC die 104 and IC die 136 may include, or be a part of, one or more of a central processing unit (CPU), a memory device, e.g., a high bandwidth memory device, a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art.

In some embodiments, the IC dies (e.g., 104, 136) in microelectronic assembly 100 may comprise the materials discussed above with regard to IC dies in general. In various embodiments, FLI 136 and MLI 126 may comprise the same or different types of DTD interconnects as described above. SLI 124 between substrate 102 and a motherboard (or other such component) may comprise DTPS interconnects as described above. In many embodiments, MLI 126 may be formed with a looser pitch and/or coarser design rules or critical dimensions than FLI 146 between IC die 104 and substrate 106. Note that according to currently accepted terminology among those with ordinary skill in the art, FLI refers to the interconnection between the IC dies and other components; MLI refers to the interconnection between the interposer or patch substrate and the package substrate; and SLI refers to the interconnection between the package substrate and the PCB.

Note that in FIG. 1A and in subsequent figures, the interconnects between various components are shown as aligned at the respective interfaces merely for ease of illustration; in actuality, some or all of them may be misaligned. In addition, there may be other components, such as bond pads, landing pads, seed layers, adhesive layers, metallization, etc. present in the assembly that are not shown in the figures to prevent cluttering. Note that FIG. 1A and subsequent figures are intended to show relative arrangements of the components within their assemblies, and that, in general, such assemblies may include other components that are not illustrated (e.g., various interfacial layers or various other components related to optical functionality, electrical connectivity, or thermal mitigation). For example, in some further embodiments, the assembly as shown in FIG. 1A may include more dies along with other electrical components. Additionally, although some components of the assemblies are illustrated in FIG. 1A and subsequent figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

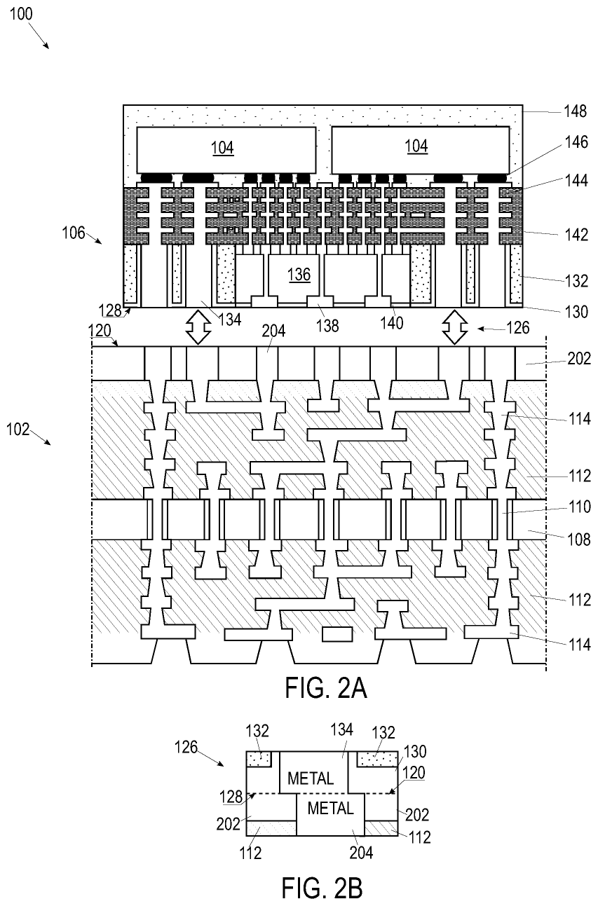

FIG. 2A is a schematic cross-sectional illustration of a portion of a microelectronic assembly 100, according to some embodiments of the present disclosure. The example embodiment shown comprises substrate 102 to which is coupled one or more of IC die 104 with substrate 106. In various embodiments, substrate 102 comprises a package substrate and substrate 106 comprises an interposer in some embodiments, and a patch substrate in other embodiments. In various other embodiments, substrate 102 and substrate 106 are interchangeable.

In the example embodiment shown, substrate 102 comprises a core 108 with through-vias 110, which may also function as inductors in certain embodiments. As discussed with respect to FIG. 1A, core 108 may comprise FR-4 in some embodiments, and an inorganic insulator, such as glass or ceramic, in other embodiments. Dielectric 112 may encapsulate core 108 on either side. Conductive traces 114, including vias, planes and pads, may be provided on either side of core 108 through dielectric 112 using any suitable conductive material, such as copper. In various embodiments, dielectric 112 and conductive traces 114 may be formed as a plurality of alternating layers with conductive vias through dielectric 112 providing electrical coupling between two or more metal layers. In some embodiments (not shown), solder resist 116 may be disposed on an opposite side of side 120; in other embodiments (as shown), dielectric 112 may function as an appropriate solder resist material.

In the example embodiment as shown, substrate 102 includes a coating 202 comprising a layer of glass on side 120 proximate to substrate 106. The glass used in coating 202 comprises an oxide of silicon, such as plain glass, borosilicate glass, etc., uncombined with ceramic or organic materials. Coating 202 may provide a stiff, planar surface with sufficiently low TTV to facilitate MLI 126 comprising hybrid bonds between side 120 of substrate 102 and side 128 of substrate 106. Coating 202 comprises one or more of conductive via 204 suitably patterned therein to expose conductive contacts therethrough. Conductive via 204 is electrically coupled to conductive traces 114.

IC die 136 may be embedded inside mold compound 132 (e.g., attached within a cavity) with a suitable adhesive, for example, comprising an industry-standard die attach material, such as liquid epoxy or polyimide film. In some embodiments, for example, as shown, IC die 136 is flush with side 128 of substrate 106; in other embodiments (not shown), embedded IC die 136 may be located within a cavity spaced apart from side 128 by mold compound 132, with TMVs providing electrical coupling appropriately (e.g., see FIG. 12E). In some embodiments where IC die 136 is flush with side 128 and has TSVs, one or more conductive contact 138 and coating 140 comprised of silicon oxide, conductive contact 138 may bond with the conductive contact exposed by conductive via 204; likewise coating 140 may bond with coating 202 of substrate 102, forming further MLI 126 comprising hybrid bonds between IC die 136 and substrate 102.

A detailed view of MLI 126 between substrate 102 and substrate 106 is shown in FIG. 2B. Conductive contacts on surfaces of side 120 and side 128 of substrate 102 and substrate 106 respectively (e.g., conductive contacts exposed through vias 204 and 134) bond with each other; likewise, silicon oxide in coating 130 of substrate 106 and glass, comprising an oxide of silicon, in coating 202 of substrate 102 bond with each other. The bonded interconnects form MLI 126, comprising hybrid bonds, providing electrical and mechanical coupling between substrates 102 and 106. Coating 118 and coating 202 enable planar, flat surfaces on side 120 and side 128 of substrate 102 and substrate 106 respectively such that hybrid bonding processes can be used to form MLI 126 comprising hybrid bonds.

Other components shown in FIGS. 2A and 2B are analogous to those shown in FIGS. 1A and 1B and therefore will not be discussed further for the sake of brevity.

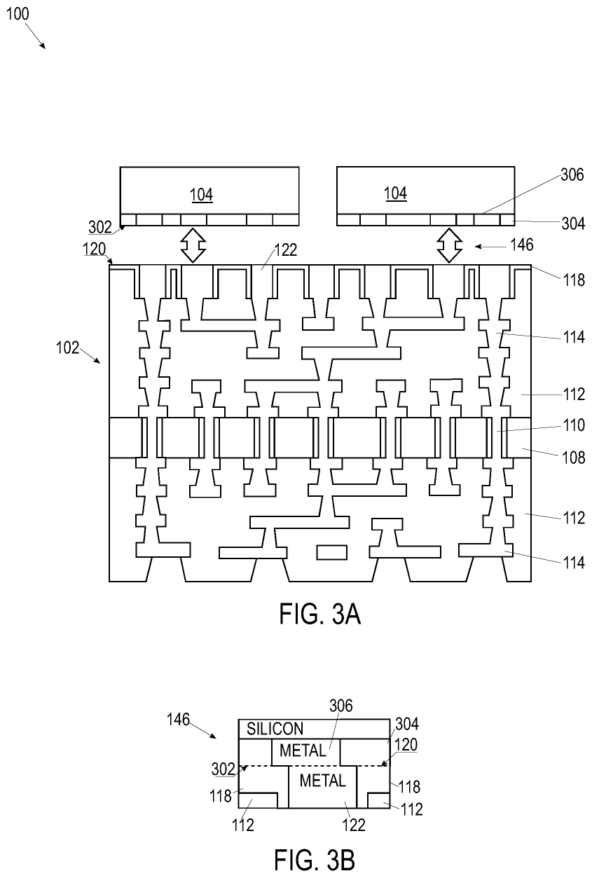

FIG. 3A is a schematic cross-sectional illustration of a portion of a microelectronic assembly 100, according to some embodiments of the present disclosure. The example embodiment shown comprises substrate 102 to which is directly coupled one or more IC die 104 without any intermediate patch substrate or interposer (e.g., substrate 106). In the example embodiment shown, substrate 102 comprises a core 108 with through-vias 110, which may also function as inductors in certain embodiments. As discussed with respect to FIG. 1A, core 108 may comprise FR-4 in some embodiments, and an inorganic insulator, such as glass or ceramic, in other embodiments. Dielectric 112 may encapsulate core 108 on either side. Conductive traces 114, including vias, planes and pads, may be provided on either side of core 108 through dielectric 112 using any suitable conductive material, such as copper. In various embodiments, dielectric 112 and conductive traces 114 may be formed as a plurality of alternating layers with conductive vias through dielectric 112 providing electrical coupling between two or more metal layers. Solder resist 116 may be located as an outermost insulating layer on either side of substrate 102. In some embodiments (as shown), dielectric 112 may function as a solder resist material on one or both sides of substrate 102.

Coating 118 comprising silicon oxide encapsulates dielectric 112 on side 120 proximate to IC die 104. Note that in embodiments where solder resist 116 is used (e.g., as shown in FIG. 1A), coating 118 encapsulates solder resist 116. Coating 118 may provide a stiff, planar surface with sufficiently low TTV to facilitate FLI 146 between side 120 of substrate 102 and a side 302 of IC die 104. FLI 146 comprises hybrid bonds in various embodiments. IC die 104 comprises a coating 304 of silicon oxide and one or more conductive contact 306 exposed through vias therein. Note that coating 304 and conductive contact 306 are comprised in a metallization stack including layers of conductive traces in ILD typically used in semiconductor dies. These details are not shown in the figure so as not to clutter the drawing.

A detailed view of FLI 146 is shown in FIG. 3B. Conductive contacts exposed through conductive via 122 on surface of side 120 of substrate 102 and conductive contact 306 exposed on surface 302 of IC die 104 bond with each other; likewise, silicon oxide in coating 118 of substrate 102 and in coating 304 of IC die 104 bond with each other. The bonded interconnects form FLI 146, comprising hybrid bonds, providing electrical and mechanical coupling between substrate 102 and IC die 104. Such hybrid bonds are known in the art as a form of interconnect between semiconductor dies; they are not known to be used to connect IC dies to organic substrates as described herein. The reason for their lack of use in such applications is the inability, using current techniques and processes, to create planar surfaces on organic materials with sufficiently low TTV to enable metal-to-metal contact and simultaneous oxide-to-oxide contact such that a bond is created with no interstitial holes and other irregularities that could lead to electrical shorts, electrical opens and/or other performance degradations. However, in embodiments of the present disclosure, this disadvantage is mitigated by the use of coating 118 over underlying organic material, namely dielectric 112 (and/or solder resist 116). Coating 118 provides a sufficiently planar surface to enable creating a reliable hybrid bond between IC die 104 and substrate 102 comprising organic materials, such as dielectric 112.

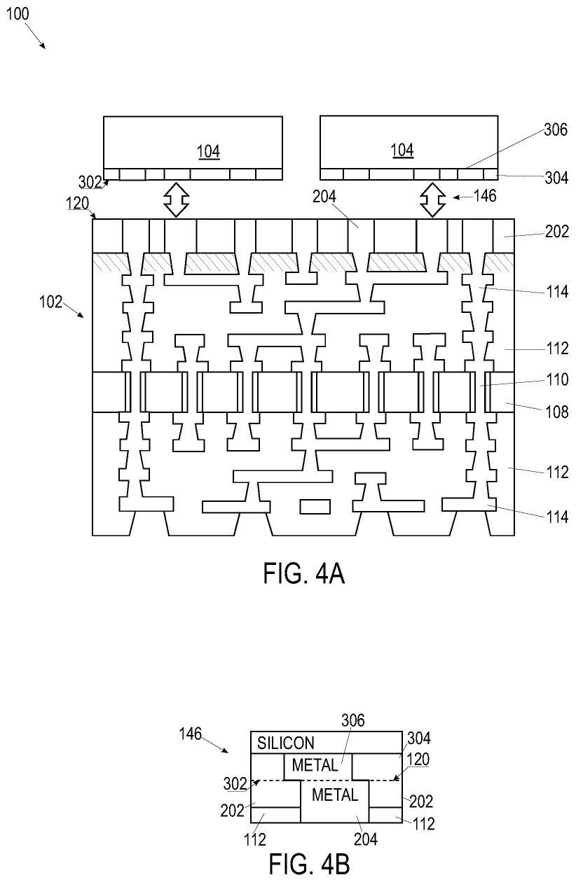

FIG. 4A is a schematic cross-sectional illustration of a portion of a microelectronic assembly 100, according to some embodiments of the present disclosure. The example embodiment shown comprises substrate 102 to which is directly coupled one or more IC die 104 without any intermediate patch substrate or interposer (e.g., substrate 106). In the example embodiment shown, substrate 102 comprises a core 108 with through-vias 110, which may also function as inductors in certain embodiments. As discussed with respect to FIG. 1A, core 108 may comprise FR-4 in some embodiments, and an inorganic insulator, such as glass or ceramic, in other embodiments. Dielectric 112 may encapsulate core 108 on either side. Conductive traces 114, including vias, planes and pads, may be provided on either side of core 108 through dielectric 112 using any suitable conductive material, such as copper. In various embodiments, dielectric 112 and conductive traces 114 may be formed as a plurality of alternating layers with conductive vias through dielectric 112 providing electrical coupling between two or more metal layers. In some embodiments (not shown), solder resist 116 may be disposed on an opposite side of side 120; in other embodiments (as shown), dielectric 112 may function as an appropriate solder resist material.

In the example embodiment as shown, substrate 102 includes coating 202 comprising glass on side 120 proximate to IC die 104. The glass used in coating 202 comprises an oxide of silicon, such as plain glass, borosilicate glass, etc., uncombined with ceramic or organic materials. As discussed with regard to FIG. 2A, coating 202 may provide a stiff, planar surface with sufficiently low TTV to facilitate FLI 146 comprising hybrid bonds between IC die 104 and substrate 102. Coating 202 comprises one or more of conductive via 204 suitably patterned therein to expose conductive contacts electrically coupled to conductive traces 114. IC die 104 comprises coating 304 of silicon oxide and one or more conductive contact 306 exposed through vias therein. Coating 304 and conductive contact 306 are comprised in a metallization stack including layers of conductive traces in ILD typically used in semiconductor dies. These details are not shown in the figure so as not to clutter the drawing.

A detailed view of FLI 146 is shown in FIG. 4B. Conductive contacts exposed through conductive via 204 on surface of side 120 of substrate 102 and conductive contact 306 exposed on surface 302 of IC die 104 bond with each other; likewise, glass, comprising oxides of silicon in coating 202 of substrate 102 and silicon oxide in coating 304 of IC die 104 bond with each other. The bonded interconnects form FLI 146, comprising hybrid bonds, providing electrical and mechanical coupling between substrate 102 and IC die 104. Coating 202 comprising glass provides a sufficiently planar surface on side 120 of substrate 102 to enable reliable hybrid bonds between IC die 104 and substrate 102 comprising organic materials, such as dielectric 112.

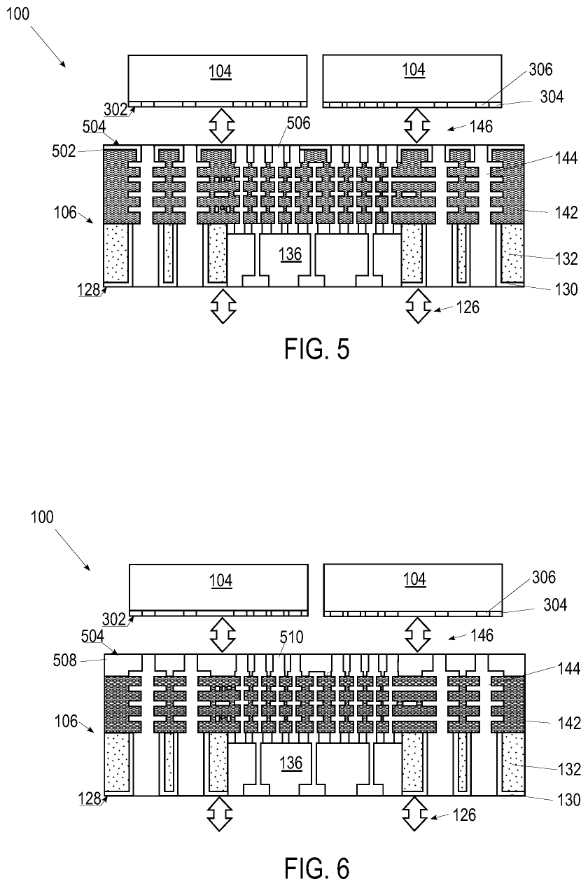

FIG. 5 is a schematic cross-sectional illustration of a portion of a microelectronic assembly 100, according to some embodiments of the present disclosure. Substrate 106 includes mold compound 132, comprising a suitable epoxy resin, in which is embedded IC die 136. Mold compound 132 may be encapsulated on side 128 with coating 130 comprising silicon oxide. Substrate 106 may further comprise dielectric 142 and conductive traces 144 that together constitute an appropriate RDL. In various embodiments, the RDL may comprise one layer each of dielectric 142 and conductive traces 144; in other embodiments, the RDL may comprise multiple alternating layers of dielectric 142 and conductive traces 144 with conductive vias between two or more metal layers. In the embodiment shown, a coating 502 comprising silicon oxide may encapsulate dielectric 142 on a side 504 proximate to IC die 104 and opposite to side 128, with one or more conductive via 506 patterned suitably to expose conductive contacts (e.g., bond pads) and electrically coupled to conductive traces 144. In some embodiments, based on the process used to deposit coating 502, sidewalls of the one or more conductive via 506 may be coated with the material as well. In various embodiments, coating 502 may provide a stiff (e.g., rigid), planar surface on side 504 with sufficiently low TTV to facilitate FLI 146 comprising hybrid bonds between substrate 106 and IC die 104.

In the example embodiment shown, one or more IC die 104 comprises coating 304 of silicon oxide and one or more conductive contact 306 exposed through vias therein. Coating 304 and conductive contact 306 are comprised in a metallization stack including layers of conductive traces in ILD typically used in semiconductor dies. These details are not shown in the figure so as not to clutter the drawing.

Conductive contacts exposed through conductive via 506 on surface of side 504 of substrate 106 and conductive contact 306 exposed on surface 302 of IC die 104 bond with each other; likewise, silicon oxide in coating 502 of substrate 106 and in coating 304 of IC die 104 bond with each other. The bonded interconnects form FLI 146, comprising hybrid bonds, providing electrical and mechanical coupling between substrate 106 and IC die 104. Thus, substrate 106 in the example embodiment shown may couple to IC die 104 on side 504 and to substrate 102 (not shown) on side 128 with hybrid bonds; that is, both FLI 146 and MLI 126 may comprise hybrid bonds.

FIG. 6 is a schematic cross-sectional illustration of a portion of a microelectronic assembly 100, according to some embodiments of the present disclosure. Substrate 106 includes mold compound 132, comprising a suitable epoxy resin, in which is embedded IC die 136. Mold compound 132 may be encapsulated on side 128 with coating 130 comprising silicon oxide. Substrate 106 may further comprise dielectric 142 and conductive traces 144 that together constitute an appropriate RDL. In various embodiments, the RDL may comprise one layer each of dielectric 142 and conductive traces 144; in other embodiments, the RDL may comprise multiple alternating layers of dielectric 142 and conductive traces 144 with conductive vias between two or more metal layers. In the example embodiment as shown, substrate 106 includes coating 508 comprising a layer of glass on side 504 proximate to IC die 104. The glass used in coating 508 comprises an oxide of silicon, such as plain glass, borosilicate glass, etc., uncombined with ceramic or organic materials. Coating 508 may provide a stiff, planar surface with sufficiently low TTV to facilitate FLI 146 comprising hybrid bonds between substrate 106 and IC die 104. Coating 508 comprises one or more conductive via 510 suitably patterned therein to expose conductive contacts of conductive traces 144.

In the example embodiment shown, one or more IC die 104 may be coupled to substrate 106 on side 504 with FLI 146. IC die 104 comprises coating 304 of silicon oxide and one or more conductive contact 306 exposed through vias therein. Coating 304 and conductive contact 306 are comprised in a metallization stack including layers of conductive traces in ILD typically used in semiconductor dies. These details are not shown in the figure so as not to clutter the drawing.

Conductive contacts exposed through conductive via 510 on surface of side 504 of substrate 106 and conductive contact 306 exposed on surface 302 of IC die 104 bond with each other; likewise, glass, comprising oxides of silicon in coating 508 of substrate 106 and silicon oxide in coating 304 of IC die 104 bond with each other. The bonded interconnects form FLI 146, comprising hybrid bonds, providing electrical and mechanical coupling between substrate 106 and IC die 104. Coating 508 comprising glass provides a sufficiently planar surface on side 502 of substrate 106 to enable reliable hybrid bonds between IC die 104 and substrate 106 comprising organic materials, such as dielectric 142. Thus, substrate 106 in the example embodiment shown may couple to IC die 104 on side 504 and to substrate 102 (not shown) on side 128 with hybrid bonds; that is, both FLI 146 and MLI 126 may comprise hybrid bonds.

Note that although not shown in figures, in various embodiments, the planar surfaces with low TTV created on substrate 102 by coating 118 or coating 202 and on substrate 106 by coating 502 or coating 508 may enable other kinds of interconnects besides hybrid bonds. For example, FLI 146 and/or MLI 126 may also comprise solder-based interconnects comprising copper pillars with solder caps as discussed previously. Among any type of interconnects used in the semiconductor industry today, hybrid bonds require the lowest TTV for reliable bonding. Because the planar surfaces formed at die-to-substrate or substrate-to-substrate interfaces described herein can enable such hybrid bonds, they can also enable bonds that do not require low TTV in the coupling interfaces.

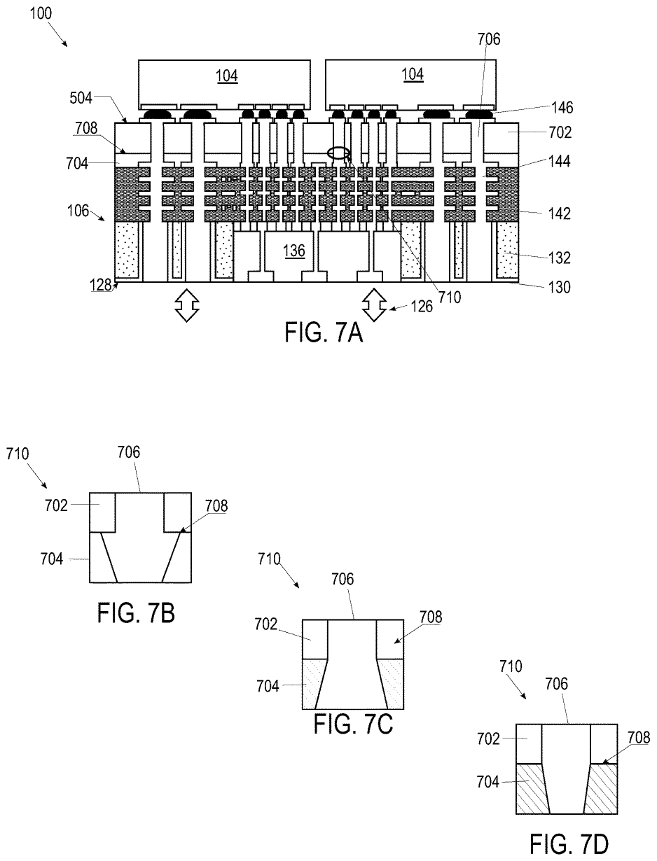

FIG. 7A is a schematic cross-sectional illustration of a portion of a microelectronic assembly 100, according to some embodiments of the present disclosure. The example embodiment shown comprises IC die 104 coupled to substrate 106. Substrate 106 includes an embedded IC die 136 in some embodiments as discussed with respect to FIG. 1A. In other embodiments, IC die 136 may not be included in substrate 106.

In the embodiment shown, a template 702 may be attached to dielectric 142 proximate to IC die 104 by an attachment layer 704. In some embodiments, template 702 may comprise any suitable structure with low TTV, such as ceramic, glass or even rigid epoxy mold. In many embodiments, a minimum thickness of template 702 is limited by handling, for example, based on current handling machines which can accommodate a thickness of 100 micrometer. With handling improvements and/or material enhancements the minimum thickness of template 700 may be reduced further appropriately.

Attachment layer 704 comprises any suitable low modulus material that can absorb differences in surface thickness variations between template 702 and dielectric 142. In some embodiments, attachment layer 704 may comprise several layers of a suitable attachment material, such as ABF, polyimide bond film, etc. In other embodiments, attachment layer 704 may comprise a single layer of the attachment material. In some embodiments, attachment layer 704 may comprise layers of different materials, such as a dielectric and bond film. In some other embodiment, attachment layer 704 may comprise only bond film (e.g., in cases where electrical properties are not critical to performance). In various embodiments, a self-aligning patterning process of one or more vias, such as via 706 through template 702 can enable high-density bump pitch with potentially low true position error, low warpage, and low BTV.

In embodiments in which template 702 comprises glass or other oxide of silicon, template 702 may be analogous to, and comprise, coating 508 of the embodiment described with reference to FIG. 6 (or coating 202 of the embodiment described with reference to FIG. 2A), and FLI 146 may comprise hybrid bonds in such embodiments. In such embodiments (not shown), conductive contacts exposed through via 706 on side 504 of substrate 106 may be flush with the surface of template 702 to enable forming the hybrid bonds as shown in FIG. 6. In other embodiments where FLI 146 comprises other kinds of interconnects (as shown), such as copper bumps with solder caps (e.g., C2 bumps) or flip-chip bumps (e.g., C4 bumps), conductive contacts exposed through via 706 on side 504 of substrate 106 may extend outwards from the surface of template 702 to enable forming such bonds.

In various embodiments, in addition to providing a low TTV surface to enable forming reliable hybrid bonds, template 702 can also function as a mask to enable forming via 706 therethrough with pitches as low as 25 um without the need of a patch and/or full panel glass handling during substrate manufacturing. The stiff material used for template 702 can result in low warpage and low TTV at FLI 146 because attachment layer 704 together with template 702 effectively absorbs any warpage or thickness variation of underlying dielectric 142 within substrate 106. Further, template 702 provides a flat surface for high-yield FLI 146 during assembly. Rigid template 702 comprising materials having a low coefficient of thermal expansion (CTE), such as glass, can also enable low shrinkage in substrate 106 during assembly processes, which enables lower true position error, for example, on account of a fixed scaling of template 702 combined with predictable shrinkage due to better dimensional stability of template 702.

In some embodiments, template 702 may be used on substrate 102, in which case, an intermediate patch substrate (such as substrate 106) may be dispensed with, translating to improved power delivery performance and lower cost. In addition, as described further below, using template 702 rather than forming the substrate around a glass core can enable ease of manufacturability and assembly, while reaping the benefits of glass, such as low warpage, low TTV, and reduced shrinkage. This translates to significant capex reduction for repurposing substrate manufacturing infrastructure with glass handling capability. Additionally, it does not require glass scribing during substrate package manufacturing or assembly.

A self-aligning patterning process used with template 702 can result in a particular via profile at a surface 708 underneath template 702. For example, a detail 710 of a via profile is shown in FIGS. 7B-7D for three different self-aligning patterning processes. In a self-aligning patterning process as described herein, unlike in conventional patterning processes, template 702, which forms a part of the structure, is used as a pattern to generate vias elsewhere in the structure, namely, underneath template 702, such as in attachment layer 704 and/or dielectric 142. In conventional patterning processes, on the other hand, an external pattern is used to generate vias in different (e.g., successive) layers; misalignment in the placement of the external pattern can cause misalignment of vias generated in these layers, resulting in manufacturing yield loss and operational defects, among other issues. Even if the same pattern is used for each layer, discrepancies in the pattern placement between successive layer formation can result in misalignment. Such defects are mitigated in the self-aligned patterning process of the various embodiments described herein.

FIG. 7B shows the via profile for a self-aligned dry etch process. Some undercut beneath surface 708 may be present in via 706 when the self-aligned dry etch process is used to generate vias with template 702.

FIG. 7C shows the via profile for a self-aligned etching process using a positive type of photo-sensitive material (e.g., photo-imageable dielectric, solder resist, etc.). The via profile of via 706 exhibits a positive taper (i.e., a flare) with zero misalignment at an interface with template 702; i.e., a first size of via 706 distant from template 702 is larger than a second size of via 706 proximate to template 702. The zero misalignment follows from the self-aligning process used as described in greater detail below.

FIG. 7D shows the via profile for a self-aligned etching process using a negative type of photo-sensitive material (e.g., photo-imageable dielectric, solder resist, etc.). The via profile of via 706 exhibits a negative type taper (e.g., narrowing) with zero misalignment at an interface with template 702; i.e., a first size of via 706 distant from template 702 is smaller than a second size of via 706 proximate to template 702. The zero misalignment follows from the self-aligning process used as described in greater detail below.

Note that although FIGS. 7A-7D are described with respect to substrate 106, the processes and structures described can be adapted easily to substrate 102 within the broad scope of the embodiments of the present disclosure.

In various embodiments, any of the features discussed with reference to any of FIGS. 1A-7D herein may be combined with any other features to form a package with one or more ICs as described herein, for example, to form a modified microelectronic assembly 100. Some such combinations are described above, but, in various embodiments, further combinations and modifications are possible.

### Example Methods

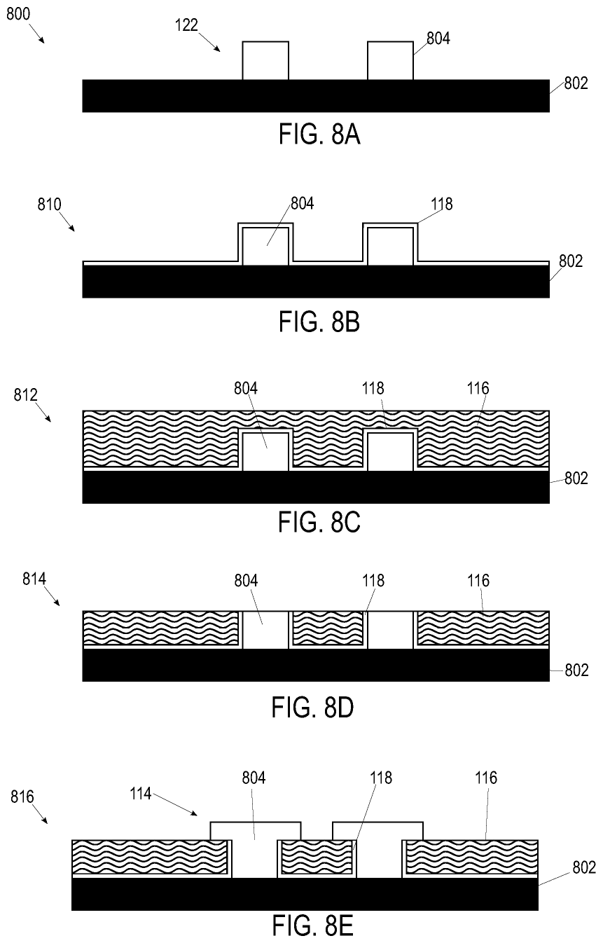

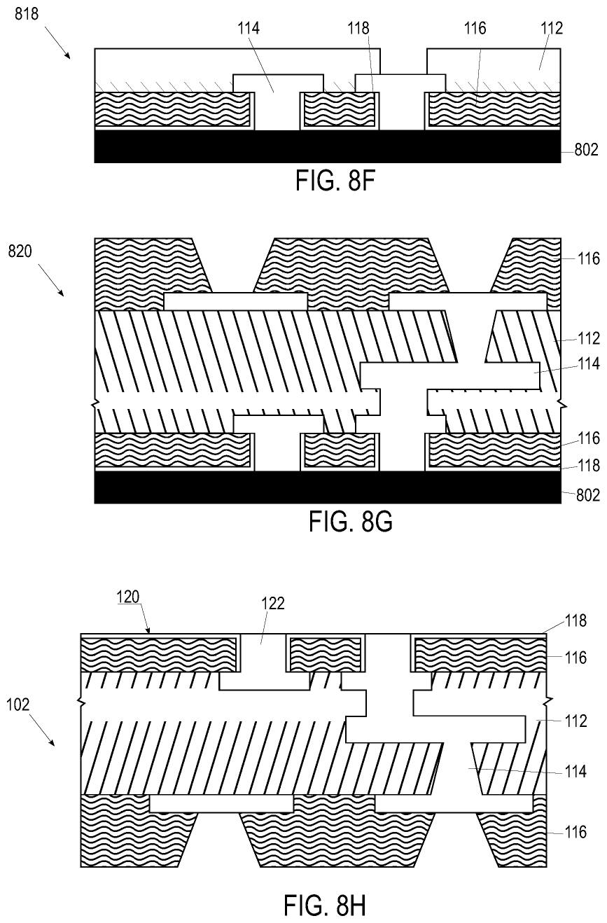

FIGS. 8A-8H are schematic cross-sectional illustrations of various stages of manufacture of substrate 102, according to some embodiments of the present disclosure. FIG. 8A shows an assembly 800 comprising a carrier 802, on which metallization 804 is deposited according to a pattern of the one or more conductive via 122 as described in FIG. 1A. Carrier 802 may comprise glass in some embodiments; in other embodiments, carrier 802 may comprise ceramic material, or metal, or other stiff, hard, and inert material. Carrier 802 may comprise a panel in some embodiments, for example, with area of 510×515 square millimeter, or 600×600 square millimeter; in other embodiments, carrier 802 may comprise a wafer, for example, 300 millimeter in diameter. Deposited metallization 804 may comprise a seed layer of titanium and/or nickel in addition to copper.

The process then proceeds to form assembly 810 of FIG. 8B, shown after depositing a coating of coating 118 comprising silicon oxide over metallization 804. In various embodiments, coating 118 may be deposited by conformal sputtering such that silicon oxide blankets substantially all surfaces over carrier wafer 802, including deposited metallization 804.

The process then proceeds to form assembly 812 of FIG. 8C, shown after depositing solder resist 116 over coating 118. In some embodiments, solder resist 16 may be deposited as a film, for example, through a lamination process; in other embodiments, solder resist 16 may be deposited in liquid form and subsequently cured, for example, with heat or ultraviolet (UV) light. In embodiments in which dielectric 112 is used instead of solder resist 116, dielectric 112 may be deposited at this step.

The process then proceeds to form assembly 814 of FIG. 8D, shown after a planarization process to reveal a surface of underlying metallization 804. The planarization process removes not only solder resist 116, but also coating 118 over metallization 804 to reveal the surface of metallization 804. Any suitable planarization process may be used, including chemical mechanical polishing (CMP), or electrochemical techniques known in the art.

The process then proceeds to form assembly 816 of FIG. 8E, shown after additional metallization comprising conductive traces 114. In various embodiments, copper metallization may be added through an electroplating process followed by etching according to a trace pattern as known in the art.

The process then proceeds to form assembly 818 of FIG. 8F, shown after depositing dielectric 112 over solder resist 116, and forming vias therein.

The process then proceeds to form assembly 820 of FIG. 8G, shown after building up substrate 102, for example, repeating depositing metal, patterning traces, adding dielectric 112, and forming one of more vias, until substrate 102 with the desired structure is formed on carrier 802. Note that only a partial buildup is shown in the figure so as not to clutter the drawings. In many embodiments, core 108, comprising FR-4, prepreg, or glass (and other such stiff inorganic materials) may be stitched into the buildup appropriately using methods known in the art. In the example embodiment shown in the figure, solder resist 116 is shown on either side of substrate 102. In other embodiments, as discussed in preceding figures, dielectric 112 may be used throughout instead if the material is suitable enough (e.g., the material can be patterned suitably; it functions similar to a photoresist for solder-based interconnects, etc.).

The process then proceeds to complete formation of substrate 102 as shown in FIG. 8H, in which substrate 102 is diced from the assembly, carrier 802 is removed and substrate 102 inverted so that side 120 is exposed for further assembly processing, such as attachment of substrate 106 or IC die 104. In this process flow, KGDs can be assembled after RDL generation, allowing for less risky and/or less costly processing compared to other process flows where KGDs are assembled before RDL generation.

Although FIGS. 8A-8H illustrate various operations performed in a particular order, this is simply illustrative, and the operations discussed herein may be reordered and/or repeated as suitable. For example, one or more operations may be performed in parallel to manufacture multiple microelectronic assemblies substantially simultaneously. In another example, the operations may be performed in a different order to reflect the structure of a particular microelectronic assembly. Numerous other variations are also possible to achieve the desired structure of microelectronic assembly 100. Further, additional processes which are not illustrated may also be performed without departing from the scope of the present disclosure. For example, the operations may include various cleaning operations, surface planarization operations (e.g., using CMP), operations for surface roughening, operations to include barrier and/or adhesion layers as desired, and/or operations for incorporating packages as described herein in, or with, an IC die, a computing device, or any desired structure or device. Also, various ones of the operations discussed herein with respect to FIGS. 8A-8H may be modified in accordance with the present disclosure to fabricate substrate 106 discussed herein. For example, coating 130 (or coating 502) instead of coating 118 may be formed on carrier 802 of FIG. 8B; mold compound 132 (or dielectric 142) instead of solder resist 116 may be deposited in the process shown in FIG. 8C; dielectric 142 instead of dielectric 112 may be built up over mold compound 132 in the process shown in FIG. 8F and so on.

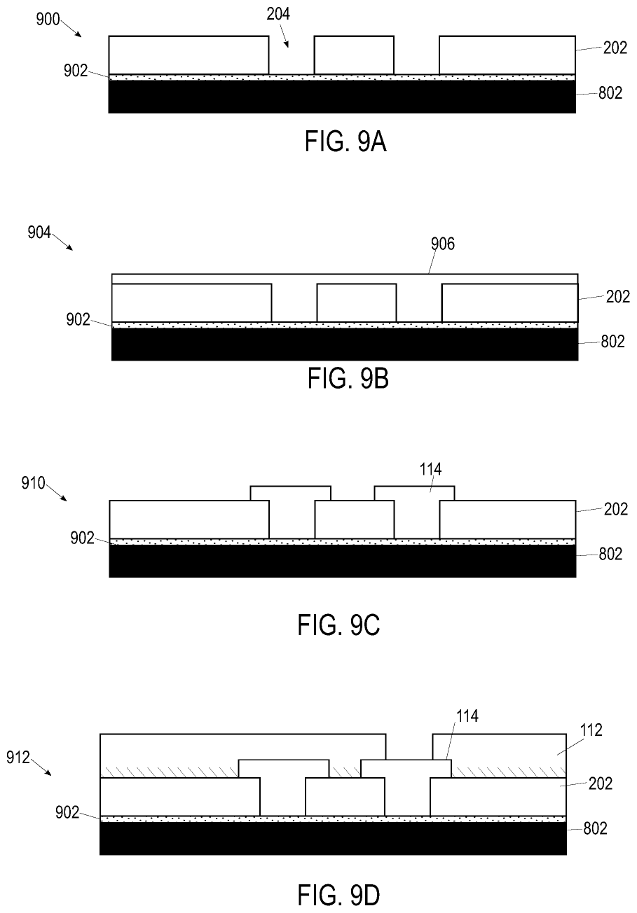

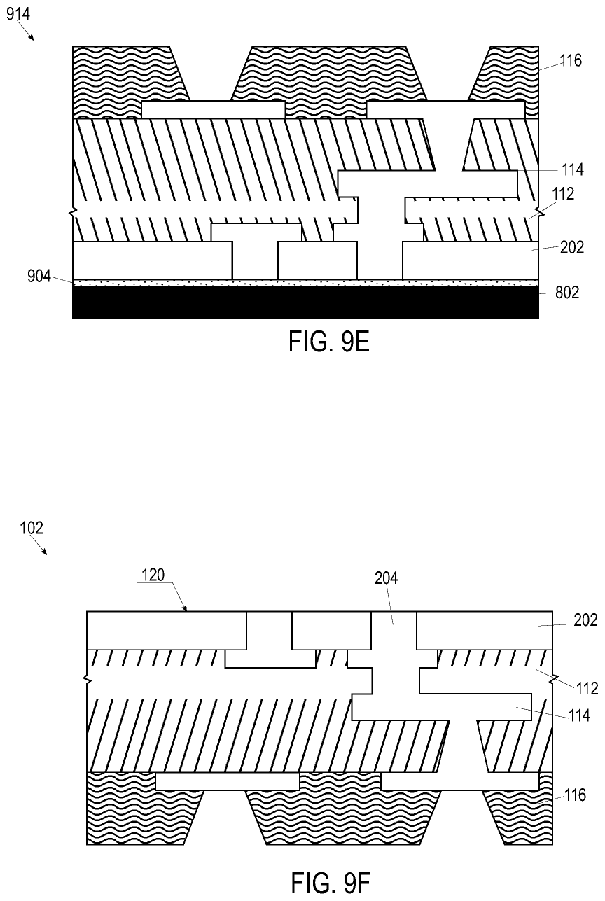

FIGS. 9A-9F are schematic cross-sectional illustrations of various stages of manufacture of substrate 102, according to some embodiments of the present disclosure. The process starts as shown in FIG. 9A with assembly 900 comprising a carrier 802 on which is attached coating 202 comprising a layer of glass, for example in the form of a glass panel or wafer of suitable thickness. Coating 202 may be attached to carrier 802 with a suitable removable adhesive 902. Coating 202 may be prepatterned with the one or more of conductive via 204 before attaching on carrier 802 in some embodiments. In other embodiments, coating 202 may be patterned with the one or more of conductive via 122 after attaching to carrier 802.

The process then proceeds to form assembly 904 of FIG. 9B, shown after deposition of metal 906 over coating 202. The metal may be deposited using any suitable process known in the art, such as electroplating.

The process then proceeds to form assembly 910 of FIG. 9C, shown after a planarization and/or patterning process forming metal planes, pads, traces, etc. of conductive traces 114.

The process then proceeds to form assembly 912 of FIG. 9D, shown after deposition of dielectric 112 over coating 202 and patterned traces followed by via formation (e.g., by lithography or laser drilling).

The process then proceeds to form assembly 914 of FIG. 9E, shown after building up substrate 102, for example, by repeating the processes of depositing metal, patterning it suitably, depositing further dielectric 112, forming vias, and so on. Note that only a partial buildup is shown in the figure so as not to clutter the drawings. In many embodiments, core 108, comprising FR-4, prepreg, or glass (and other such stiff inorganic materials) may be stitched into the buildup appropriately using methods known in the art. In the example embodiment shown in the figure, solder resist 116 is shown on the side opposite to coating 202. In other embodiments, as discussed in preceding figures, dielectric 112 may be used throughout instead if the material is suitable enough (e.g., the material can be patterned suitably; it functions similar to a photoresist for solder-based interconnects, etc.).

The process then proceeds to complete formation of substrate 102 as shown in FIG. 9F, in which substrate 102 is diced from the assembly, carrier 802 is removed and substrate 102 inverted so that side 120 is exposed for further assembly processing, such as attachment of substrate 106 or IC die 104. In this process flow, KGDs can be assembled after RDL generation, allowing for less risky and/or less costly processing compared to other process flows where KGDs are assembled before RDL generation.

Although FIGS. 9A-9F illustrate various operations performed in a particular order, this is simply illustrative, and the operations discussed herein may be reordered and/or repeated as suitable. For example, one or more operations may be performed in parallel to manufacture multiple microelectronic assemblies substantially simultaneously. In another example, the operations may be performed in a different order to reflect the structure of a particular microelectronic assembly. Numerous other variations are also possible to achieve the desired structure of microelectronic assembly 100. Further, additional processes which are not illustrated may also be performed without departing from the scope of the present disclosure. For example, the operations may include various cleaning operations, surface planarization operations (e.g., using CMP), operations for surface roughening, operations to include barrier and/or adhesion layers as desired, and/or operations for incorporating packages as described herein in, or with, an IC die, a computing device, or any desired structure or device. Also, various ones of the operations discussed herein with respect to FIGS. 9A-9F may be modified in accordance with the present disclosure to fabricate others of microelectronic assembly 100 disclosed herein. Also, various ones of the operations discussed herein with respect to FIGS. 9A-9F may be modified in accordance with the present disclosure to fabricate substrate 106 discussed herein. For example, coating 508 instead of coating 202 may be formed on carrier 802 of FIG. 9A; mold compound 132 (or dielectric 142) instead of dielectric 112 may be deposited in the process shown in FIG. 9D; dielectric 142 instead of dielectric 112 may be built up over mold compound 132 in the process shown in FIG. 9E and so on.

FIG. 10A is a simplified schematic cross-sectional view of substrate 106 according to an embodiment of the present disclosure. Different processes may be used to extend vias 506 in template 702 into attachment layer 704 according to the via pattern in template 702. In some embodiments, a dry etching process may be used to extend vias 506 into attachment layer 704. In such embodiments, template 702 can function as a hard mask while underlying metalized landing pads of conductive traces 144 act as etch stops. As shown in greater detail in FIG. 10B, such a process can create an undercut beneath surface 708 in via 706. Note that the detail shown in FIG. 10B is of an intermediate process step, in which via formation has not advanced fully. The completed via extends through attachment layer 704 (and/or dielectric 142 as appropriate) until the etch stop, for example, underlying metallization, and includes the undercut at the interface with template 702 as shown.

In other embodiments, a photoimaging process under UV light may be used with positive type photo-sensitive materials that become active (e.g., soluble) when exposed to UV light. In such embodiments, the material of attachment layer 704 comprises such positive type photo-sensitive material. As shown in greater detail in FIG. 10C, positive type photo-sensitive material comprising attachment layer 704 becomes soluble or active, for example, transforming into material 1014 when exposed to UV light. Material 1014 can be removed in standard developing solutions to extend via 706 into attachment layer 704. In some embodiments that use this process, template 702 comprises an opaque material that blocks UV light and creates an embedded contact mask. In some other embodiments that use this process, template 702 comprises dyed glass, for example, dyes doped into the glass or reflective films deposited on its surface to block the UV light.

In yet other embodiments, a photoimaging process under UV light may be used with negative type photo-sensitive materials that cure when exposed to UV light. In such embodiments, the material of attachment layer 704 comprises such negative type photo-sensitive material. As shown in greater detail in FIG. 10D, template 702 can comprise a UV transparent material, for example, plain glass. In such embodiments, an opaque plug 1016 can be temporarily filled in via 706 to block UV light and act as an embedded contact mask. The material comprising attachment layer 704 is cured (e.g., cross-linked) when exposed to UV light and material 1018 in the via that is unexposed to UV light remains uncured, and can be removed using standard developing solutions.

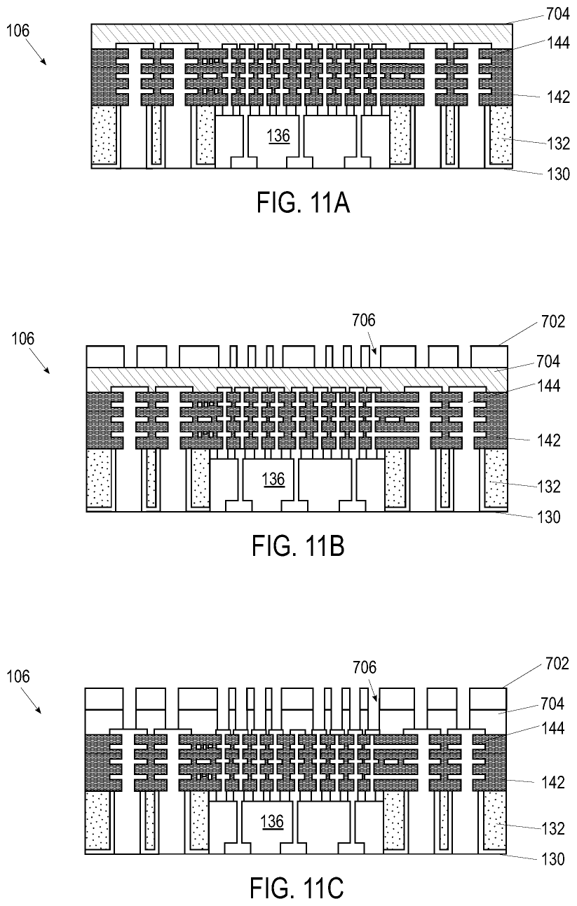

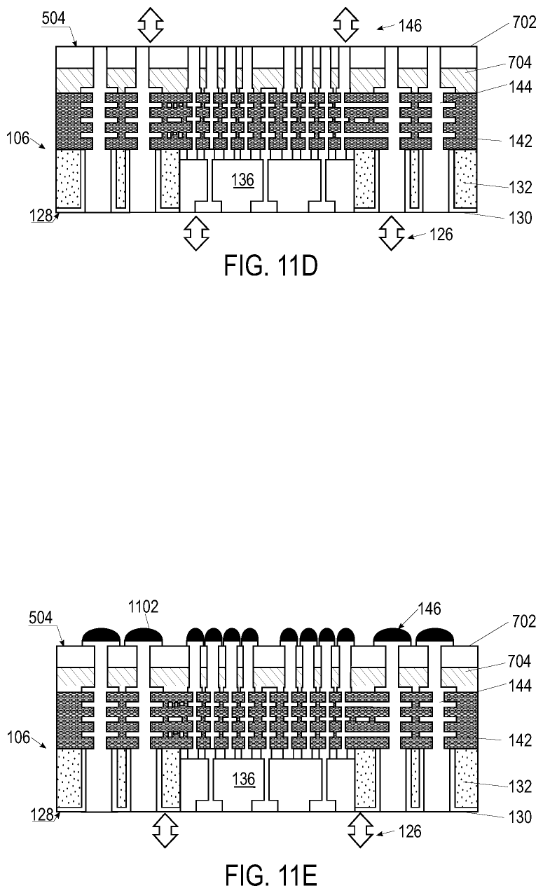

FIGS. 11A-11G are schematic cross-sectional illustrations of various stages of manufacture of substrate 106, according to some embodiments of the present disclosure. FIGS. 8A-9F illustrated methods of manufacture comprising an additive process of building up substrate 102 layer by layer, starting from side 120. FIGS. 11A-11G show an alternate method applicable to embodiments in which template 702 or coating 202 or coating 508 is used. FIG. 11A shows substrate 106 on which attachment layer 704 has been deposited. The method of deposition of attachment layer 704 on substrate 106 may depend on the specific material used. For example, if the material of attachment layer 704 is a film, attachment layer 704 may be laminated on substrate 106; if the material of attachment layer 704 is a liquid in uncured form, the material may be sprayed or layered on substrate 106 and then cured appropriately. Note that substrate 106 may be in panel form at this stage, with multiple individual units that may be diced apart later in the process as described below.

The process then steps to the structure shown in FIG. 11B, after attaching template 702 on attachment layer 704 using unit-level fiducial alignment (e.g., alignment based on individual units rather than at a panel-level). The template attach process aligns to within unit fiducials following standard fiducial alignment techniques, similar in manner to die alignment/placement. Template 702 can be sized to fit the entire unit or multiple ones of template 702 can be stitched together within the panel. Template 702 can also be prepatterned with cavities or openings for various components including high bandwidth memory, die-side capacitors, or other passives as may be desired and based on particular needs in addition to via 706 for conductive contacts. In various embodiments, template 702 is prepatterned with a via pattern for the one or more of via 706. Template 702 may be glued to attachment layer 704 by pressing.

The process then steps to the structure shown in FIG. 11C, after etching through attachment layer 704 to extend the one or more of via 706 to underlying conductive pads of conductive traces 144. Following the template attach process as described with respect to FIG. 11B, the self-aligned pattern is then created in attachment layer 704, which forms a patterning material. An optional planarization step may precede the self-aligned patterning to provide a flat surface for template placement (e.g., a “regeneration layer”).

In some embodiments, the process then steps to form the structure shown in FIG. 11D, after a semi-additive process in which metal is added in the one or more of via 706 in template 702. Any suitable means, such as sputter seed deposition of titanium, nickel, or copper; followed by resist lamination; and then patterning and electroplating or electroless deposition may be used to add metal. In some embodiments, more metal than is necessary is added, followed by an etching process to remove excess metal. In other embodiments, the surface of template 702 is planarized so that side 504 has low TTV sufficient for hybrid bond formation. In various embodiments, after resist and seed removal, the panel is cut into quarter-panels for assembly and ultimately diced into units. At this stage, substrate 106 is substantially complete and ready to be coupled to IC die 104 on side 504 with FLI 146 and/or to substrate 102 on side 128 with MLI 126.

In some other embodiments, the process steps from forming the structure described with reference to FIG. 11C to the structure shown in FIG. 11E, after depositing metal in the one or more of via 706 followed by patterning and plating metal to form conductive contacts and traces on side 504 of template 702. Any suitable means, such as sputter seed deposition of titanium, nickel, or copper; followed by resist lamination; and then patterning and electroplating or electroless deposition may be used to add metal. Such a structure may be used, for example, in embodiments where FLI 146 comprises solder-based interconnects. In such embodiments, nickel/tin may be patterned on metal pads at side 504 of template 702 followed by application of solder paste and a subsequent reflow process to form one or more of solder bump 1102 that can be used to generate solder-based FLI 146. Side 128 may be coupled to substrate 102 (not shown) with MLI 126 comprising, for example, hybrid bonds.

Although FIGS. 11A-11E illustrate various operations performed in a particular order, this is simply illustrative, and the operations discussed herein may be reordered and/or repeated as suitable. For example, one or more operations may be performed in parallel to manufacture multiple substrates substantially simultaneously. In another example, the operations may be performed in a different order to reflect the structure of a particular substrate. Numerous other variations are also possible to achieve the desired structure of microelectronic assembly 100. Further, additional processes which are not illustrated may also be performed without departing from the scope of the present disclosure. For example, the operations may include various cleaning operations, surface planarization operations (e.g., using CMP), operations for surface roughening, operations to include barrier and/or adhesion layers as desired, and/or operations for incorporating packages as described herein in, or with, an IC die, a computing device, or any desired structure or device. Also, various ones of the operations discussed herein with respect to FIGS. 11A-11E may be modified in accordance with the present disclosure to fabricate substrate 102 discussed herein. For example, attachment layer 704 may be deposited on dielectric 112 of substrate 102 instead of dielectric 142 as shown in FIG. 11A and subsequent steps followed accordingly.

FIGS. 12A-12F are schematic cross-sectional illustrations of various stages of manufacture of substrate 106, according to some embodiments of the present disclosure. FIGS. 8A-9F illustrated methods of manufacture comprising an additive process of building up substrate 102 layer by layer, starting from side 120. FIGS. 11A-11E showed an alternate method applicable to embodiments in which template 702 or coating 202 or coating 508 is used. FIGS. 12A-12F show yet another alternate method, for example, adapted to cases in which the BTV with the method of FIGS. 11A-11E is too high for reliable FLI formation. In some embodiments that utilize this method, substrate 106 may not comprise metallization on the side of embedded IC die 136 proximate to FLI 146. In other embodiments that utilize this method, substrate 106 may comprise such metallization; in such embodiments, power routing within such metallization layer between bridge die 136 and FLI 146 may need to be aligned to the self-aligned patterning process described herein and any alignment error must be accounted for appropriately.

FIG. 12A shows substrate 106 on which attachment layer 704 has been deposited. Note that embedded IC die 136 shown in the example embodiment sits within a cavity spaced apart from side 128 by mold compound 132, with TMVs providing electrical coupling suitably through mold compound 132. In other embodiments (e.g., as shown in FIG. 1A), IC die 136 may be flush with side 128. The method of deposition of attachment layer 704 on substrate 106 may depend on the specific material used. For example, if the material of attachment layer 704 is a film, attachment layer 704 may be laminated on substrate 106; if the material of attachment layer 704 is a liquid in uncured form, the material may be sprayed or layered on substrate 106 and then cured appropriately. Note that substrate 106 may be in panel form at this stage, with multiple individual units that may be diced apart later in the process as described below.

The process then steps to the structure shown in FIG. 12B, after attaching template 702 on attachment layer 704 using unit-level fiducial alignment (e.g., alignment based on individual units rather than at the panel-level). The template attach process aligns to within unit fiducials following standard fiducial alignment techniques, similar in manner to die alignment/placement. Template 702 can be sized to fit the entire unit or multiple ones of template 702 can be stitched together within the panel. Template 702 can also be prepatterned with cavities or openings for various components including high bandwidth memory, die-side capacitors, or other passives as may be desired and based on particular needs in addition to via 706 for conductive contacts. In various embodiments, template 702 is prepatterned with a via pattern for the one or more of via 706. Template 702 may be glued to attachment layer 704 by pressing.

The process then steps to the structure shown in FIG. 12C, after etching through attachment layer 704 to extend the one or more of via 706 to underlying conductive pads of conductive traces 144. In some embodiments in which metallization between IC die 136 and attachment layer 704 is absent (as shown), the etching process may extend via 706 to the surface of embedded IC die 136.

The process then steps to the structure shown in FIG. 12D, after depositing a blanket layer of metal on template 702 followed by planarizing the surface of the metal. The metal fills the one or more of via 706, thereby joining with conductive traces 144. Any suitable means, such as sputter seed deposition of titanium, nickel, or copper; followed by resist lamination; and then patterning and electroplating or electroless deposition may be used to add metal. The surface of the metal may be planarized using any suitable means known in the art.

In some embodiments, the process then steps to form the structure shown in FIG. 12E, after a semi-additive process in which metal is added in the one or more of via 706. Any suitable means, such as sputter seed deposition of titanium, nickel, or copper; followed by resist lamination; and then patterning and electroplating or electroless deposition may be used to add metal. In some embodiments, more metal than is necessary is added, followed by an etching process to remove excess metal. In other embodiments, the surface of template 702 is planarized so that side 504 has low TTV sufficient for hybrid bond formation. In various embodiments, after resist and seed removal, the panel is cut into quarter-panels for assembly and ultimately diced into units. At this stage, substrate 106 is substantially complete and ready to be coupled to IC die 104 on side 504 with FLI 146 and/or to substrate 102 on side 128 with MLI 126. In such embodiments, FLI 146 and MLI 126 may comprise hybrid bonds.

In some other embodiments, the process steps from forming the structure described with reference to FIG. 12D to the structure shown in FIG. 12F, after depositing metal in the one or more of via 706 followed by patterning and plating metal to form conductive contacts and traces on side 504 of template 702. Any suitable means, such as sputter seed deposition of titanium, nickel, or copper; followed by resist lamination; and then patterning and electroplating or electroless deposition may be used to add metal. Such a structure may be used, for example, in embodiments where FLI 146 comprises solder-based interconnects. In such embodiments, nickel/tin may be patterned on metal pads at side 504 of template 702 followed by application of solder paste and a subsequent reflow process to form one or more of solder bump 1102 that can be used to generate solder-based FLI 146. Side 128 may be coupled to substrate 102 (not shown) with MLI 126 comprising, for example, hybrid bonds.

Although FIGS. 12A-12F illustrate various operations performed in a particular order, this is simply illustrative, and the operations discussed herein may be reordered and/or repeated as suitable. For example, one or more operations may be performed in parallel to manufacture multiple substrates substantially simultaneously. In another example, the operations may be performed in a different order to reflect the structure of a particular substrate. Numerous other variations are also possible to achieve the desired structure of substrate 106. Further, additional processes which are not illustrated may also be performed without departing from the scope of the present disclosure. For example, the operations may include various cleaning operations, surface planarization operations (e.g., using CMP), operations for surface roughening, operations to include barrier and/or adhesion layers as desired, and/or operations for incorporating packages as described herein in, or with, an IC die, a computing device, or any desired structure or device. Also, various ones of the operations discussed herein with respect to FIGS. 12A-12F may be modified in accordance with the present disclosure to fabricate substrate 102 discussed herein. For example, attachment layer 704 may be deposited on dielectric 112 instead of dielectric 142 as shown in FIG. 12A and subsequent steps followed accordingly.

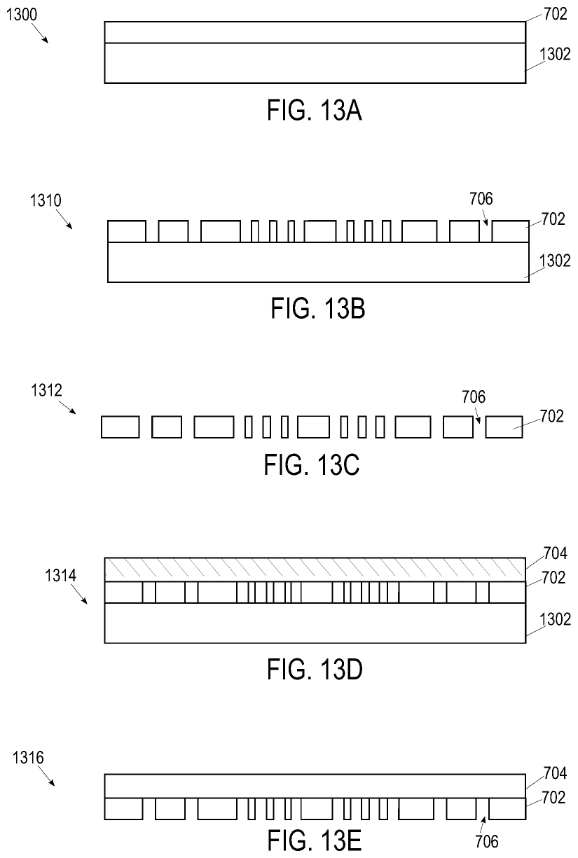

FIGS. 13A-13F are schematic cross-sectional illustrations of various stages of manufacture of template 702, according to some embodiments of the present disclosure. As shown in assembly 1300 of FIG. 13A, template 702 is fabricated on a carrier 1302 and diced into individual units (or sub-units), separate from the substrate package manufacturing and assembly process.

The process then proceeds to form assembly 1310 shown in FIG. 13B, after forming the one or more of via 706. In some embodiments in which template 702 comprises glass, via 706 may be formed by applying a light induced etching (LIDE), which may be suitable for creating high aspect ratio through-holes in glass (e.g., as high as 9:1 length to diameter). In various embodiments, the LIDE process may comprise two steps: in the first step, the glass of template 702 is locally modified by laser pulses according to a desired layout, for example, via pattern of the one or more of via 706; in the second step, the modified areas of the glass are removed by wet chemical etching, for example, with hydrofluoric acid, which removes the modified material more rapidly than the unmodified material.

In some embodiments, the process then proceeds to form assembly 1312 shown in FIG. 13C, after removing carrier 1302. Subsequently, individual units of template 702 may be formed subsequently by appropriately dicing assembly 1312.

In some other embodiments, the process proceeds from assembly 1310 of FIG. 13B to form assembly 1314 of FIG. 13D, after laminating or otherwise depositing attachment layer 704 over template 702. In some embodiments, attachment layer 704 may comprise a polyimide bond film or other material that can be patterned.

The process then proceeds to form assembly 1316 of FIG. 13E, after removing carrier 1302. Assembly 1316 may be subsequently diced into individual units and attached to substrate 106 suitably as discussed previously.

Although FIGS. 13A-13E illustrate various operations performed in a particular order, this is simply illustrative, and the operations discussed herein may be reordered and/or repeated as suitable. For example, one or more operations may be performed in parallel to manufacture multiple templates substantially simultaneously. In another example, the operations may be performed in a different order to reflect the structure of a particular template. Numerous other variations are also possible to achieve the desired structure of template 702. Further, additional processes which are not illustrated may also be performed without departing from the scope of the present disclosure. For example, the operations may include various cleaning operations, surface planarization operations (e.g., using CMP), operations for surface roughening, operations to include barrier and/or adhesion layers as desired.

### Example Devices and Components

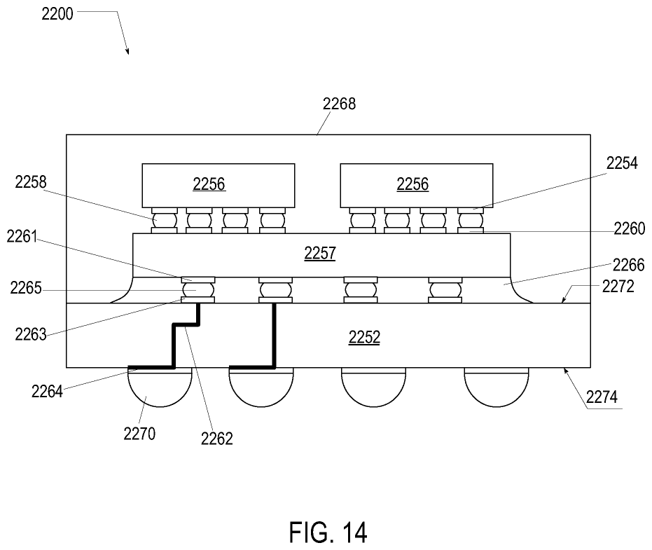

The packages disclosed herein, e.g., any of the embodiments shown in FIGS. 1A-12F or any further embodiments described herein, may be included in any suitable electronic component. FIGS. 14-16 illustrate various examples of packages, assemblies, and devices that may be used with or include any of the IC packages as disclosed herein.

FIG. 14 is a side, cross-sectional view of an example IC package 2200 that may include microelectronic assemblies in accordance with any of the embodiments disclosed herein. In some embodiments, the IC package 2200 may be a system-in-package (SiP).

As shown in FIG. 14, package support 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias, e.g., as discussed above with reference to FIG. 1.

Package support 2252 may include conductive contacts 2263 that are coupled to conductive pathway 2262 through package support 2252, allowing circuitry within dies 2256 and/or interposer 2257 to electrically couple to various ones of conductive contacts 2264 (or to other devices included in package support 2252, not shown).

IC package 2200 may include interposer 2257 coupled to package support 2252 via conductive contacts 2261 of interposer 2257, FLI 2265, and conductive contacts 2263 of package support 2252. FLI 2265 illustrated in FIG. 14 are solder bumps, but any suitable FLI 2265 may be used, such as solder bumps, solder posts, or bond wires.

IC package 2200 may include one or more dies 2256 coupled to interposer 2257 via conductive contacts 2254 of dies 2256, FLI 2258, and conductive contacts 2260 of interposer 2257. In various embodiments, interposer 2257 may include coating 118 (or 202 or similar coatings) as described herein. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). FLI 2258 illustrated in FIG. 14 are solder bumps, but any suitable FLI 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

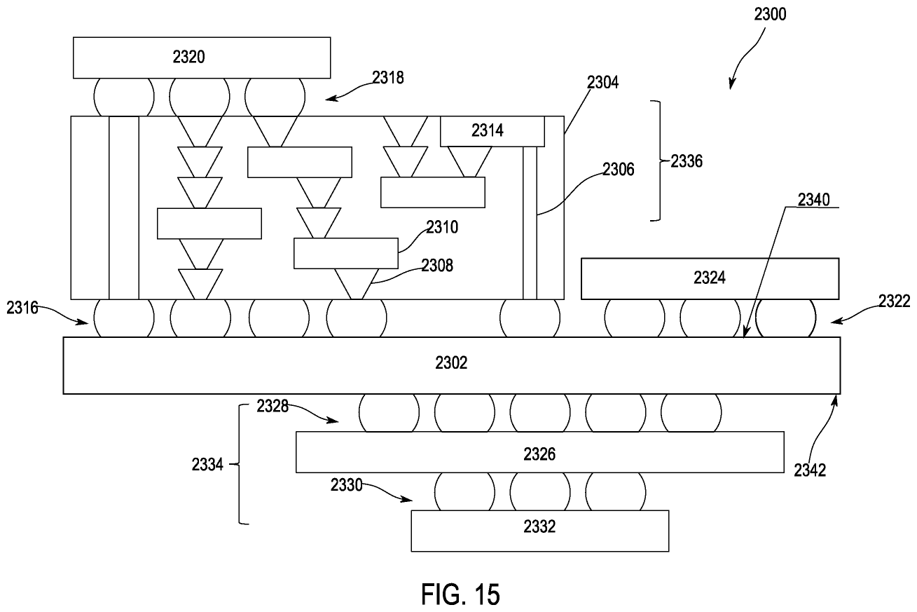

In some embodiments, underfill material 2266 may be disposed between package support 2252 and interposer 2257 around FLI 2265, and mold 2268 may be disposed around dies 2256 and interposer 2257 and in contact with package support 2252. In some embodiments, underfill material 2266 may be the same as mold 2268. Example materials that may be used for underfill material 2266 and mold 2268 are epoxies as suitable. SLI 2270 may be coupled to conductive contacts 2264. SLI 2270 illustrated in FIG. 14 are solder balls (e.g., for a ball grid array (BGA) arrangement), but any suitable SLI 2270 may be used (e.g., pins in a pin grid array arrangement or lands in a land grid array arrangement). SLI 2270 may be used to couple IC package 2200 to another component, such as a circuit board (e.g., a motherboard), an interposer, or another IC package, as known in the art and as discussed below with reference to FIG. 15.

In embodiments in which IC package 2200 includes multiple dies 2256, IC package 2200 may be referred to as a multi-chip package (MCP). Dies 2256 may include circuitry to perform any desired functionality. For example, besides one or more of dies 2256 comprising components of IC dies 112 or 114 as described herein, one or more of dies 2256 may be logic dies (e.g., silicon-based dies), one or more of dies 2256 may be memory dies (e.g., high bandwidth memory), etc. In some embodiments, at least some of dies 2256 may not include components of IC dies 112 or 114 as described herein.

Although IC package 2200 illustrated in FIG. 14 is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package support 2252, or on either face of interposer 2257. More generally, IC package 2200 may include any other active or passive components known in the art.

FIG. 15 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 14.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package support.

FIG. 15 illustrates that, in some embodiments, IC device assembly 2300 may include a package-on-interposer structure 2336 coupled to first face 2340 of circuit board 2302 by coupling components 2316. Although not shown so as not to clutter the drawing, package-on-interposer structure 2336 may comprise a glass core, such as core 104 in some embodiments. In other embodiments, package-on-interposer structure 2336 may not comprise any glass core. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. In some embodiments, IC package 2320 may comprise microelectronic assembly 100 having components as described herein, which are not shown so as not to clutter the drawing. Coupling components 2318 may take any suitable form depending on desired functionalities, such as the forms discussed above with reference to coupling components 2316. In some embodiments, IC package 2320 may be or include IC package 2200, e.g., as described above with reference to FIG. 14.

Although a single IC package 2320 is shown in FIG. 15, multiple IC packages may be coupled to interposer 2304; indeed, additional interposers may be coupled to interposer 2304. Interposer 2304 may provide an intervening package support used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in FIG. 15, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

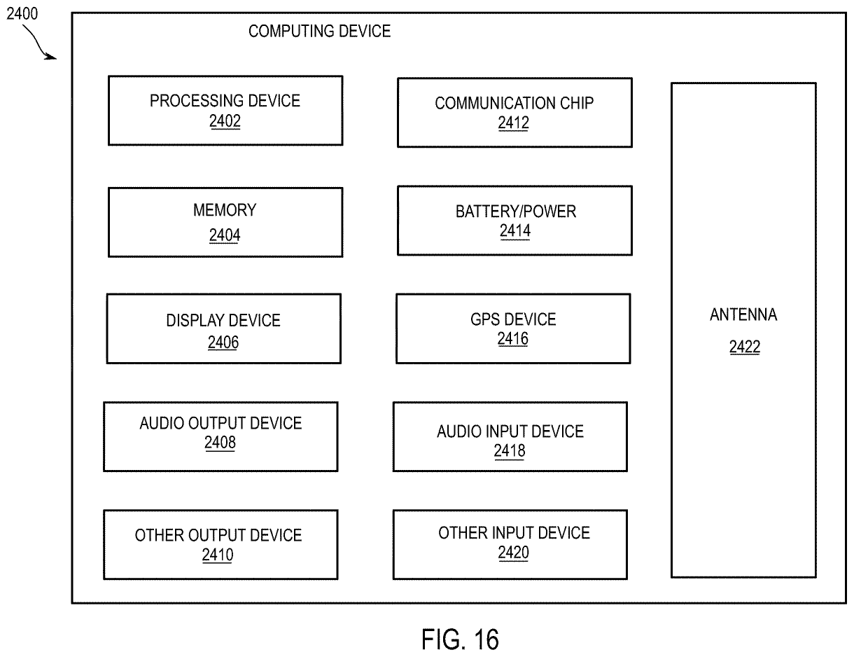

FIG. 16 is a block diagram of an example computing device 2400 that may include one or more components having one or more IC packages in accordance with any of the embodiments disclosed herein. For example, any suitable ones of the components of computing device 2400 may include microelectronic assembly 100 in accordance with any of the embodiments disclosed herein. In another example, any one or more of the components of computing device 2400 may include any embodiments of IC package 2200 (e.g., as shown in FIG. 14). In yet another example, any one or more of the components of computing device 2400 may include an IC device assembly 2300 (e.g., as shown in FIG. 15).

A number of components are illustrated in FIG. 16 as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in FIG. 16, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips; note that the terms “chip,” “die,” and “IC die” are used interchangeably herein). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives of it, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### SELECT EXAMPLES

The following paragraphs provide various examples of the embodiments disclosed herein.

Example 1 provides a substrate (e.g., 102, 106) of a microelectronic assembly (e.g., 100), the substrate comprising: conductive traces (e.g., 114, 144) through an organic dielectric (e.g., 112, 142); and a coating (e.g., 118, 202, 502, 508, 702) comprising silicon and oxygen. The substrate is configured to couple with a component (e.g., 106, 102, or 104) electrically and mechanically by at least one or more conductive vias (e.g., 122, 204, 506, 510, 706) through the coating, the one or more conductive vias being electrically connected to the conductive traces, such that the coating is between the organic dielectric and the component when coupled.

Example 2 provides the substrate of example 1, in which the coating comprises a layer of glass (e.g., 202, 508, 702).

Example 3 provides the substrate of example 2, further comprising an attachment layer (e.g., 704) between the layer of glass and the organic dielectric (e.g., FIG. 7A).

Example 4 provides the substrate of example 3, where the attachment layer comprises the organic dielectric.

Example 5 provides the substrate of example 3, where the attachment layer comprises a plurality of layers of another organic dielectric.

Example 6 provides the substrate of example 3, where the attachment layer comprises at least a first layer of another organic dielectric and a second layer of a bond film.

Example 7 provides the substrate of example 3, where the attachment layer comprises one layer of a bond film.

Example 8 provides the substrate of example 3, where the one or more conductive vias extend through the attachment layer to an underlying metallization of the conductive traces beneath the attachment layer.

Example 9 provides the substrate of example 8, in which the one or more conductive vias through the attachment layer comprise an undercut under the coating (e.g., FIG. 7B) with substantially no misalignment at an interface of the coating with the attachment layer.

Example 10 provides the substrate of example 8, in which the one or more conductive vias through the attachment layer comprise a flare under the coating (e.g., FIG. 7C) with substantially no misalignment at an interface of the coating with the attachment layer.

Example 11 provides the substrate of example 8, in which the one or more conductive vias through the attachment layer comprise a taper under the coating (e.g., FIG. 7D) with substantially no misalignment at an interface of the coating with the attachment layer.

Example 12 provides the substrate of any of examples 1-2, in which the coating comprises a first coating, and the one or more conductive vias comprise a first set of conductive vias, the component includes a second coating (e.g., 130) comprising silicon and oxygen, and a second set of conductive vias (e.g., 134) through the second coating, and the first set of conductive vias and the first coating are configured to bind with the second set of conductive vias and the second coating respectively to form hybrid bonds.

Example 13 provides the substrate of any of examples 1-2, in which the coating is in contact with the organic dielectric.

Example 14 provides the substrate of any of examples 1-2, further comprising solder resist (e.g., 116) between the coating and the organic dielectric.

Example 15 provides the substrate of any of examples 1-14, further comprising a core (e.g., 108), in which the organic dielectric is on either side of the core.

Example 16 provides the substrate of example 15, in which the core comprises glass.

Example 17 provides the substrate of example 15, in which the core comprises an organic material.

Example 18 provides the substrate of example 15, in which the core comprises through-vias (e.g., 110).

Example 19 provides the substrate of any of examples 1-18, in which the organic dielectric and the conductive traces comprise alternating layers, and vias filled with conductive material couple at least two layers of the conductive traces through the organic dielectric.

Example 20 provides the substrate of any of examples 1-19, in which the component comprises another substrate (e.g., 106).

Example 21 provides the substrate of example 20, in which the another substrate comprises a patch substrate.

Example 22 provides the substrate of example 20, in which the another substrate comprises an interposer.

Example 23 provides the substrate of example 20, in which an IC die (e.g., 136) is embedded in the another substrate.

Example 24 provides the substrate of any of examples 1-19, in which the component comprises an IC die (e.g., 104).

Example 25 provides the substrate of any of examples 1-24, in which: the coating is on a first side (e.g., 120), the conductive vias are configured to couple with the component by interconnects of a first type (e.g., MLI 126), and the substrate is configured to couple with a PCB on a second side (e.g., 128) opposite to the first side by interconnects of a second type (e.g., SLI 124).

Example 26 provides the substrate of example 25, in which a first pitch of the interconnects of the first type is smaller than a second pitch of the interconnects of the second type.

Example 27 provides the substrate (e.g., 106 of FIGS. 5, 6) of example 1, further comprising: a mold compound (e.g., 132); and a RDL in contact with the mold compound. The RDL comprises the organic dielectric (e.g., 142) and the conductive traces (e.g., 144), and the RDL is between the mold compound and the coating (e.g., 502, 508).

Example 28 provides the substrate of example 27, in which the coating comprises a first coating on a first side (e.g., 504), and the substrate further comprises a second coating (e.g., 130) comprising silicon and oxygen on a second side (e.g., 128) opposite to the first side. The mold compound is between the RDL and the second coating.

Example 29 provides the substrate of any one of examples 27-28, further comprising an IC die (e.g., 136) embedded in the mold compound.

Example 30 provides the substrate of example 29, in which the IC die comprises TSVs.

Example 31 provides the substrate of any of examples 28-30, in which the one or more conductive vias comprises a first set of conductive vias, and the substrate further comprises a second set of conductive vias through the second coating, wherein the second set of conductive vias are configured to couple with another component electrically and mechanically.

Example 32 provides the substrate of example 31, in which the component comprises another IC die (e.g., 104) and the another component comprises another substrate (e.g., 102).

Example 33 provides the substrate of any one of examples 27-32 in which the first substrate comprises TMVs.

Example 34 provides a microelectronic assembly (e.g., 100), comprising: an IC die (e.g., 104); a first substrate (e.g., 106) comprising a first side (e.g., 504) and a second side (e.g., 128) opposite to the first side; and a second substrate (e.g., 102), in which the first substrate is coupled to the IC die on the first side, and to the second substrate on the second side, and the first substrate includes a first coating (e.g., 130) at an interface between the first substrate and the second substrate, the second substrate includes a second coating (e.g., 118, 202) at the interface, and the first coating and the second coating comprise silicon and oxygen.

Example 35 provides the microelectronic package of example 34, in which the second coating comprises a layer of glass.

Example 36 provides the microelectronic package of any of examples 34-35, in which a first set of conductive contacts exposed through the first coating is bonded with a second set of conductive contacts exposed through the second coating at the interface.

Example 37 provides the microelectronic package of example 36, the first set of conductive contacts are bonded by solder with the second set of conductive contacts.

Example 38 provides the microelectronic package of example 36, in which the first coating is bonded with the second coating at the interface to form hybrid bonds.

Example 39 provides the microelectronic package of example 36, in which the first set of conductive contacts is exposed through a first set of conductive vias in the first coating, and the second set of conductive contacts is exposed through a second set of conductive vias in the first coating.

Example 40 provides the microelectronic package of example 39, in which the first set of conductive vias is electrically connected to a first set of conductive traces (e.g., 144) in the first substrate and the second set of conductive vias is electrically connected to a second set of conductive traces (e.g., 114) in the second substrate.

Example 41 provides the microelectronic package of any of examples 34-40, in which the first substrate further includes a mold compound (e.g., 132) and a RDL comprising an organic dielectric (e.g., 142) and conductive traces (e.g., 144), the RDL is between the IC die and the mold compound, and the first coating is between the mold compound and the interface.

Example 42 provides the microelectronic package of example 41, in which another IC die (e.g., 136) is inside a cavity in the mold compound.

Example 43 provides the microelectronic package of example 42, in which the another IC die comprises TSVs.

Example 44 provides the microelectronic package of any of examples 41-43, in which the first substrate comprises TMVs through the mold compound.

Example 45 provides the microelectronic package of any of examples 41-44, in which the first substrate further includes a third coating (e.g., 502, 508) comprising silicon and oxygen between the IC die and the RDL.

Example 46 provides the microelectronic package of example 45, further comprising: FLI comprising hybrid bonds between the IC die and the first substrate; and MLI comprising hybrid bonds between the first substrate and the second substrate.

Example 47 provides the microelectronic package of example 45, further comprising: FLI comprising solder-based bonds between the IC die and the first substrate; and MLI comprising hybrid bonds between the first substrate and the second substrate.

Example 48 provides the microelectronic package of any of examples 34-47, in which: the second substrate further includes an organic dielectric (e.g., 112) and conductive traces (e.g., 114), and the second coating is between the organic dielectric and the interface.

Example 49 provides the microelectronic package of any of examples 34-47, in which the second substrate further comprises a core (e.g., 108) with organic dielectric and conductive traces on either side of the core.

Example 50 provides the microelectronic package of example 49, in which the core comprises an organic material.

Example 51 provides the microelectronic package of example 49, in which the core comprises glass.

Example 52 provides the microelectronic package of any of examples 34-51, further comprising a mold compound (e.g., 148) over the IC die.

Example 53 provides the microelectronic package of any of examples 34-52, further comprising another IC die coupled to the first substrate on the first side.

Example 54 provides the microelectronic package of any of examples 34-53, wherein the second substrate is configured to be coupled to a PCB on a third side opposite to the first substrate.

Example 55 provides a method, comprising: on a carrier, forming a coating comprising silicon and oxygen with conductive vias therein such that the conductive vias are exposed (e.g., FIGS. 8A-8D; FIGS. 9A-9B); depositing metal over the exposed conductive vias (e.g., FIG. 8E, FIG. 9C); patterning traces in the deposited metal such that the conductive vias are coupled to the traces (e.g., FIG. 8E, FIG. 9C); adding an organic dielectric layer over the traces (e.g., FIG. 8F, FIG. 9D); forming one or more vias in the second dielectric layer (e.g., FIG. 8F, FIG. 9D); repeating depositing the metal, patterning the traces, adding the second dielectric layer, and forming the one of more vias, until a substrate with a desired structure is formed on the carrier (e.g., FIG. 8G, FIG. 9E); and removing the carrier and inverting the substrate such that the conductive vias and the coating are exposed (e.g., FIG. 8H, FIG. 9F).

Example 56 provides the method of example 55, in which the organic dielectric comprises a first dielectric, and forming the coating comprises: depositing metal corresponding to conductive vias (e.g., FIG. 8A) on the carrier; depositing the coating comprising silicon and oxygen over the carrier and the conductive vias (e.g., FIG. 8B); depositing a second dielectric over the coating (e.g., FIG. 8C); planarizing the second dielectric and the coating until a surface of the conductive vias are revealed (e.g., FIG. 8D) through the second dielectric.

Example 57 provides the method of example 56, in which the first dielectric and the second dielectric comprise the same material.

Example 58 provides the method of example 56, in which the first dielectric and the second dielectric comprise different materials.

Example 59 provides the method of example 58, in which the first dielectric comprises ABF and the second dielectric comprises solder resist.

Example 60 provides the method of example 55, in which forming the coating comprises: forming vias through a layer of glass (e.g., FIG. 9A) attached to the carrier; and depositing metal in the vias to form conductive vias through the layer of glass (e.g., FIG. 9B).

Example 61 provides the method of example 60, in which forming vias through the layer of glass comprises: on a carrier, attaching the layer of glass (e.g., FIG. 13A); modifying portions of the glass with laser pulses according to a pattern corresponding to the vias; etching the glass such that the modified portions are removed faster than the unmodified portions (e.g., FIG. 13B); and removing the carrier (e.g., FIG. 13C).

Example 62 provides the method of any of examples 55-60, in which forming one or more vias in the organic dielectric comprises laser drilling or lithography.

Example 63 provides the method of any of examples 55-62, further comprising stitching a core comprised of glass into the substrate.

Example 64 provides a method, comprising: providing a substrate comprising organic dielectric with conductive traces through the organic dielectric; depositing an attachment layer over the substrate (e.g., FIG. 11A); attaching a template over the attachment layer, wherein the template comprises vias in a via pattern (e.g., FIG. 11B); forming vias in the attachment layer using the via pattern for via placement and alignment, wherein at least a portion of the conductive traces in the dielectric function as etch stops (e.g., FIG. 11C); depositing metal in the etched vias (e.g., FIG. 11D, FIG. 11E).

Example 65 provides the method of example 64, in which forming the vias comprises dry etching.

Example 66 provides the method of example 65, in which the dry etching creates undercutting at an interface between the template and the attachment layer.

Example 67 provides the method of example 64, in which: the attachment layer comprises positive photo-sensitive material that activates under UV light, and forming the vias comprises: shining UV light through the template such that a portion of the attachment layer exposed under the via pattern to the UV light is activated; and dissolving away the activated portion of the attachment layer.

Example 68 provides the method of example 67, in which the template comprises dyed glass that blocks the UV light.

Example 69 provides the method of example 67, in which a flare is created in the via such that a first size of the via distant from the template is larger than a second size of the via proximate to the template.

Example 70 provides the method of example 64, in which: the attachment layer comprises negative photo-sensitive material that cures under UV light, and forming the vias comprises: temporarily plugging the vias in the template with opaque plugs; shining UV light through the template such that a portion of the attachment layer unexposed to the UV light under the via pattern remains uncured; and dissolving away the uncured portion of the attachment layer.

Example 71 provides the method of example 70, in which a taper in the via is created such that a first size of the via distant from the template is smaller than a second size of the via proximate to the template.

Example 72 provides the method of any of examples 64-71, further comprising forming vias in the dielectric (e.g., FIGS. 12D, 12E).

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. An assembly comprising:
a substrate having a planar outer surface, the substrate comprising:
an organic dielectric;
a conductive trace embedded in the organic dielectric, the conductive trace parallel to the outer surface of the substrate;
a glass coating over the organic dielectric, wherein a planar surface of the glass coating is coplanar with the outer surface of the substrate; and
a conductive via through the glass coating, wherein a first end of the conductive via is coplanar with the outer surface of the substrate, and a second end of the conductive via is coupled to the conductive trace;
a first die coupled to the planar outer surface of the substrate, the first die comprising a contact in contact with the conductive via through the glass coating;
a second die coupled to the first die; and
a third die coupled to the first die, wherein the first die is between the second die and the substrate, and the first die is between the third die and the substrate.

2. The assembly of claim 1, wherein the first die is a bridge die.

3. The assembly of claim 2, wherein the bridge die comprises a through via coupled to the contact.

4. The assembly of claim 1, further comprising a coating on the first die and coplanar with the contact of the first die, wherein the coating is in contact with the glass coating of the substrate.

5. The assembly of claim 4, wherein the coating on the first die is bonded to the glass coating of the substrate.

6. The assembly of claim 4, wherein the first die is at least partially embedded in a dielectric, and the coating is further between the dielectric and the glass coating.

7. The assembly of claim 6, further comprising:
a second via through the glass coating;
a third via through the glass coating;
a fourth via through the dielectric, the fourth via in contact with the second via; and
a fifth via through the dielectric, the fifth via in contact with the third via;
wherein the first die is between the fourth via and the fifth via.

8. The assembly of claim 1, wherein the glass coating is in contact with the organic dielectric.

9. The assembly of claim 1, further comprising solder resist between the glass coating and the organic dielectric.

10. The assembly of claim 1, further comprising a glass core, wherein the organic dielectric is on either side of the glass core.

11. A package comprising:
a first substrate comprising:
an organic dielectric material;
a plurality of interconnect structures embedded in the organic dielectric material;
a first outer coating over the organic dielectric material, the first outer coating having a planar surface along an outer surface of the first substrate, the first outer coating comprising glass; and
a plurality of conductive vias extending through the first outer coating, wherein a first end of one of the conductive vias is coplanar with the outer surface of the first substrate and coplanar with the planar surface of the first outer coating, and a second end of one of the conductive vias is coupled to one of the plurality of interconnect structures; and
a second substrate comprising:
a first integrated circuit (IC) die;
a second IC die;
a bridge die coupled to the first IC die and the second IC die, the bridge die comprising a contact, the contact coupled to the first end of the one of the conductive vias; and
a second outer coating on the bridge die, wherein the contact extends through the second outer coating, and the second outer coating is in contact with the first outer coating of the first substrate.

12. The package of claim 11, wherein the contact is bonded to the one of the conductive vias.

13. The package of claim 11, wherein the second substrate comprises a second organic dielectric material, and the second outer coating is between the second organic dielectric material and the first substrate.

14. The package of claim 13, wherein the second outer coating comprises silicon and oxygen.

15. The package of claim 11, wherein the first outer coating is along a first outer surface of the first substrate, the first substrate further comprising a third coating along a second outer surface of the first substrate, the second outer surface opposite the first outer surface.

16. A package comprising:
a substrate having a planar outer surface, the substrate comprising:
an organic dielectric;
a first die embedded in the organic dielectric;
a glass coating over the organic dielectric and over the first die, wherein a planar surface of the glass coating is coplanar with the outer surface of the substrate;
a first conductive via through the glass coating, wherein a first end of the first conductive via is coplanar with the outer surface of the substrate; and
a second conductive via through the glass coating, wherein a first end of the second conductive via is coplanar with the outer surface of the substrate;
a second die coupled to the planar outer surface of the substrate, the second die comprising a first contact that is in contact with the first conductive via; and
a third die coupled to the planar outer surface of the substrate, the second die comprising a second contact that is in contact with the second conductive via.

17. The package of claim 16, wherein wherein the second die further comprises a coating, wherein the first contact extends through the coating, and the coating is in direct contact with the glass coating of the substrate.

18. The package of claim 16, wherein the first die is coupled to the first conductive via and to the second conductive via.

19. The package of claim 16, wherein the planar outer surface is a first outer surface, and the substrate further comprises a second coating on a second outer surface, the second outer surface opposite the first outer surface.

20. The package of claim 19, wherein the second coating is coplanar with a surface of the first die.
